(19) United States
(12) Patent Application Publication
(10) Pub. No.: US 2026/0253192 A1
(43) Pub. Date: Aug. 27, 2026

(54) Computer, Program, and Method

(71) Applicant: Hitachi High-Tech Corporation, Minato-ku, Tokyo (JP)

(72) Inventors: Takehiro MAEDA, Tokyo (JP); Hajime KAWANO, Tokyo (JP); Mayuka OSAKI, Tokyo (JP); Minoru HARADA, Tokyo (JP); Hiroaki KASAI, Tokyo (JP); Shun KIZAWA, Tokyo (JP)

(21) Appl. No.: 19/163,705

(22) PCT Filed: Jul. 4, 2023
(86) PCT No.: PCT/JP2023/024843

§ 371 Date: Sep. 9, 2025

(51) Int. Cl. G06T 7/00

(52) U.S. Cl. CPC G06T 7/0002; G06T 2207/10061; G06T 2207/20021; G06T 2207/20081; G06T 2207/20084; G06T 2207/30168

(57) ABSTRACT

A technique capable of suitably managing a state of a charged particle beam device is provided. A storage resource stores reference data obtained by the charged particle beam device or simulation, with a sample as the target, the reference data including an imaging field coordinate of the charged particle beam device, a generation time of a reference image in which an observation region corresponding to the imaging field coordinate is captured, and a distribution of reference image quality evaluation values obtained from the reference image by an image quality evaluation function for each predetermined region. A computer (1) acquires an evaluation target image, which is obtained by the charged particle beam device, with the sample as the target and in which the observation region corresponding to the imaging field coordinate is captured, in an evaluation period including an evaluation time, (2) stores, in the storage resource, evaluation target data including the imaging field coordinate, the evaluation time, and a first distribution of image quality evaluation values obtained from the evaluation target image by the image quality evaluation function for each predetermined region, and (3) compares the reference data with the evaluation target data to calculate a distribution of temporal variations in the image quality evaluation values by the image quality evaluation function.

### TECHNICAL FIELD

The present disclosure relates to a technique of a computer or the like for managing a state of a charged particle beam device.

### Background Art

Examples of the related art include JP2022-546223A (PTL 1). PTL 1 discloses in claim 1 “a method for monitoring performance of a multi-beam system, the method comprising: receiving records of a performance metric for beams of the multi-beam system operating during an imaging process, each record associated with a beam; determining whether an abnormality of a beam occurs based on a baseline value determined using a portion of the records; and providing an abnormality indication in response to the determination that the abnormality has occurred”.

### CITATION LIST

### Patent Literature

PTL 1: JP2022-546223A

### SUMMARY OF INVENTION

### Technical Problem

In a charged particle beam device, there are a plurality of adjustment portions that affect the performance metric of a charged particle beam, in other words, an electron beam. Therefore, in order to maintain the charged particle beam device in a normal state, it is considered necessary to specify the adjustment portion based on a change in the performance metric.

For example, PTL 1 discloses that it is possible to determine whether an abnormality of a beam has occurred based on the record of the performance metric. However, in the technique as in PTL 1, there is room for consideration and improvement in estimating a state of a charged particle beam device based on the change in the performance metric. In addition, there is room for consideration and improvement in specifying an adjustment portion for correcting a beam in which an abnormality has occurred to a normal state, in other words, a correction portion.

An object of the present disclosure is to provide a technique capable of suitably managing a state of a charged particle beam device.

### Solution to Problem

A representative embodiment of the present disclosure has the following configurations. A computer according to an embodiment is a computer including a processor; and a storage resource that stores a program, in which the storage resource stores reference data obtained by a charged particle beam device or simulation, with a sample as the target, the reference data including an imaging field coordinate of the charged particle beam device, a generation time of a reference image in which an observation region corresponding to the imaging field coordinate is captured, and a distribution of reference image quality evaluation values obtained from the reference image by an image quality evaluation function for each predetermined region, and the processor that executes processing according to the program (1) acquires an evaluation target image, which is obtained by the charged particle beam device, with the sample as the target and in which the observation region corresponding to the imaging field coordinate is captured, in an evaluation period including an evaluation time, (2) stores, in the storage resource, evaluation target data including the imaging field coordinate, the evaluation time, and a first distribution of image quality evaluation values obtained from the evaluation target image by the image quality evaluation function for each predetermined region, and (3) compares the reference data with the evaluation target data to calculate a distribution of temporal variations in the image quality evaluation values by the image quality evaluation function.

### Advantageous Effects of Invention

According to a representative embodiment of the present disclosure, a state of the charged particle beam device can be suitably managed. Problems, configurations, effects, and the like other than those described above will be made clear in embodiments for carrying out the invention.

### BRIEF DESCRIPTION OF DRAWINGS

FIG. 1 is a diagram illustrating a configuration example of an observation system including a computer according to Embodiment 1.

FIG. 2 is a flowchart of main processing of the computer according to Embodiment 1.

FIG. 3 is a diagram of an image quality evaluation method in an observation region and a predetermined region in Embodiment 1.

FIG. 4 is a diagram illustrating another example of the predetermined region in Embodiment 1.

FIG. 5 is a diagram of an image quality evaluation function in Embodiment 1.

FIG. 6 is a diagram of a distribution for temporal variations in image quality evaluation values in the predetermined region in Embodiment 1.

FIG. 7A is a diagram regarding estimation of a device state using a device state DB and estimation of a correction portion using a device correction DB in Embodiment 1.

FIG. 7B is a diagram regarding a data example of the device state DB and a data example of the device correction DB in Embodiment 1.

FIG. 8A is a diagram illustrating an example of a screen including an input field as an example of a user interface in Embodiment 1.

FIG. 8B is a diagram illustrating an example of a screen including a device state monitor field as an example of the user interface in Embodiment 1.

FIG. 9 is a diagram illustrating a configuration example of a computer according to Embodiment 2.

FIG. 10 is a diagram of training of a device state estimation engine in Embodiment 2.

FIG. 11 is a diagram of estimation using the device state estimation engine in Embodiment 2.

FIG. 12 is a diagram of training of a correction portion estimation engine in Embodiment 2.

FIG. 13 is a diagram of estimation using the correction portion estimation engine in Embodiment 2.

FIG. 14 is a diagram illustrating a configuration example of a computer according to Embodiment 3.

FIG. 15 is a diagram of estimation of a device state using a multivariate distribution model in Embodiment 3.

FIG. 16 is a diagram of fitting using the multivariate distribution model in Embodiment 3.

FIG. 17 is a diagram illustrating an example of a case where pattern shapes captured in an evaluation target image and a reference image are different in Embodiment 4.

FIG. 18 is a diagram of distribution calculation using a plurality of pieces of evaluation target data and a plurality of pieces of reference data in Embodiment 4.

FIG. 19 illustrates another example of setting of a plurality of predetermined regions for a plurality of images in Embodiment 1.

FIG. 20 illustrates another display example of a distribution on the screen in Embodiment 1.

FIG. 21 illustrates an example of scanning a plurality of observation regions with a charged particle beam in Embodiment 1.

### DESCRIPTION OF EMBODIMENTS

Hereinafter, embodiments of the present disclosure will be described in detail with reference to the drawings. In the drawings, the same components are denoted by the same reference signs in principle, and repeated description thereof is omitted. In order to facilitate understanding of the invention, expressions of components in the drawings may not represent an actual position, size, shape, range, and the like.

For the sake of description, in a case of describing processing executed by a program, a program, a function, a processing unit, and the like may be described as a subject, but a subject of hardware thereof is a processor, or a controller, a device, a computer, a system or the like implemented by a processor. The computer executes processing according to the program read into a memory by the processor while appropriately using resources such as the memory and a communication interface. Accordingly, predetermined functions, processing units, and the like are implemented. The processor is implemented by, for example, a semiconductor device such as a CPU/MPU or a GPU. The processing is not limited to software program processing, and can be implemented by a dedicated circuit. The dedicated circuit may be an FPGA, an ASIC, a CPLD, or the like.

The program may be installed as data in a target computer in advance, or may be distributed as data from a program source to the target computer. The program source may be a program distribution server on a communication network, or may be a non-transitory computer-readable storage medium, for example, a memory card or a disk. The program may include a plurality of modules. A computer system may include a plurality of devices. The computer system may be implemented as a client-Server system, a cloud computing system, an IoT system, or the like. Various kinds of data and information are implemented by a structure such as a table or a list, but are not limited thereto. Expressions such as identification information, identifier, ID, name, and number are interchangeable.

### Outline of Embodiment

This embodiment provides a computer and a method of managing a state of a charged particle beam device based on a distribution of image quality evaluation values of an image captured by the charged particle beam device. A computer according to an embodiment is a computer including a processor and a storage resource that stores a device management program. A method according to an embodiment is a method executed by the computer. The computer acquires an image captured by the charged particle beam device or an image generated by simulation. In other words, the charged particle beam device is a microscope or an imaging device. The charged particle beam device is a device capable of imaging, observing, and inspecting a sample.

The storage resource stores reference data obtained by the charged particle beam device or simulation, with a sample as the target, the reference data including an imaging field coordinate of the charged particle beam device, an image in which an observation region corresponding to the imaging field coordinate is captured (may be referred to as a reference image), a generation time of the image, and a distribution of image quality evaluation values (may be referred to as reference image quality evaluation values) obtained from the reference image by an image quality evaluation function for each predetermined region. The predetermined region is a region serving as a unit for calculating the image quality evaluation value.

The processor of the computer executes the following processing according to the device management program.
(1) The processor acquires an evaluation target image, which is obtained by the charged particle beam device, with the sample as the target and in which the observation region corresponding to the imaging field coordinate is captured, in an evaluation period including an evaluation time.
(2) The processor stores, in the storage resource, evaluation target data including the imaging field coordinate of the charged particle beam device, an evaluation time, and a first distribution of image quality evaluation values obtained from the evaluation target image by the image quality evaluation function for each predetermined region.
(3) The processor compares the reference data with the evaluation target data to calculate a distribution of temporal variations in the image quality evaluation values by the image quality evaluation function. In other words, the processor compares a two-dimensional distribution of the image quality evaluation values for each predetermined region in the reference data at the generation time with a two-dimensional distribution of the image quality evaluation values for each predetermined region in the evaluation target data at a first evaluation time, calculates a temporal variation for each predetermined region, and obtains a two-dimensional distribution of the temporal variations in the image quality evaluation values.
(4) The processor estimates a state of the charged particle beam device based on the distribution of the temporal variations in the image quality evaluation values, determines correction necessity of the charged particle beam device according to the estimated state, and determines a correction portion or the like when the correction is necessary.

The computer outputs, for example, the following data and information related to the above processing to a user:
Reference data
Evaluation target data
Image quality evaluation value, temporal variation, and distribution
Estimated device state, correction necessity, and correction portion

### Embodiment 1

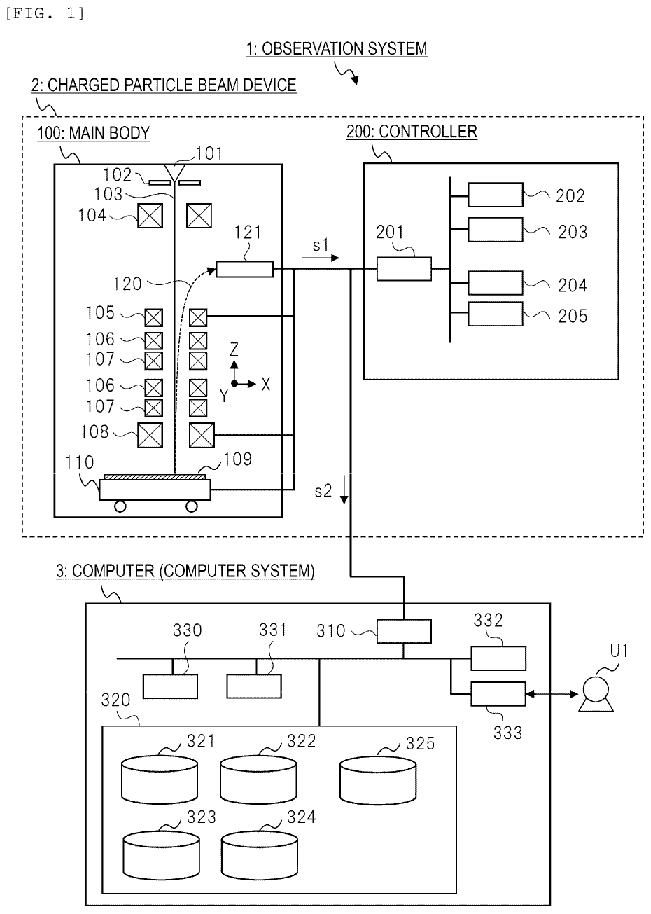

A method and a system according to Embodiment 1 of the present disclosure will be described with reference to FIGS. 1 to 8B.

In Embodiment 1, a system including a charged particle beam device and a computer is referred to as an observation system. The method according to Embodiment 1 is a method executed by the system according to Embodiment 1. In Embodiment 1, an example will be described in which a state of the charged particle beam device is estimated and corrected based on a distribution for temporal variations in image quality evaluation values of an image in a predetermined region.

### Configuration of Observation System

FIG. 1 illustrates a configuration of the observation system including the computer according to Embodiment 1. An observation system 1 in FIG. 1 includes a charged particle beam device 2 and a computer 3. The charged particle beam device 1 includes a main body 100 and a controller 200. The main body 100 includes components such as a stage serving as a sample table and a drive circuit in a housing, in other words, a column and a sample chamber. The controller 200 is a control system that drives and controls the main body 100, and can be implemented by a computer or a circuit. The computer 3, in other words, is a computer system. The observation system 1 includes components necessary for generating a signal waveform and an image based on a detection signal of the main body 100 of the charged particle beam device 2. An example of the charged particle beam device 1 is a scanning electron microscope (SEM).

The main body 100 of the charged particle beam device 2 outputs a detection signal s1 obtained based on irradiation of a sample 109 on a stage 110 with a charged particle beam 103. The controller 200 receives and processes the detection signal s1, and generates and stores a signal such as an image as a detection signal of the charged particle beam device 2. The controller 200 outputs a signal s2 such as a the image. The computer 3 receives and processes the signal s2 such as the image.

In the main body 100 of the charged particle beam device 1, the charged particle beam 103 extracted from an electron source 101 by an extraction electrode 102 is accelerated by an acceleration electrode (not illustrated). The accelerated charged particle beam 103 is focused by a condenser lens 104 which is one form of a converging lens. The focused charged particle beam 103 is corrected in an astigmatism corrector 105 to cancel astigmatism caused by an objective lens 108. The charged particle beam 103 is deflected by an image shift deflector 106 and a scanning deflector 107 to one-dimensionally or two-dimensionally scan a surface of the sample 109 on the stage 110, which is a sample table. The charged particle beam 103 is decelerated by a negative voltage applied to an electrode built in the stage 110 which is the sample table, is focused by a lens action of the objective lens 108, and is emitted onto the sample 109.

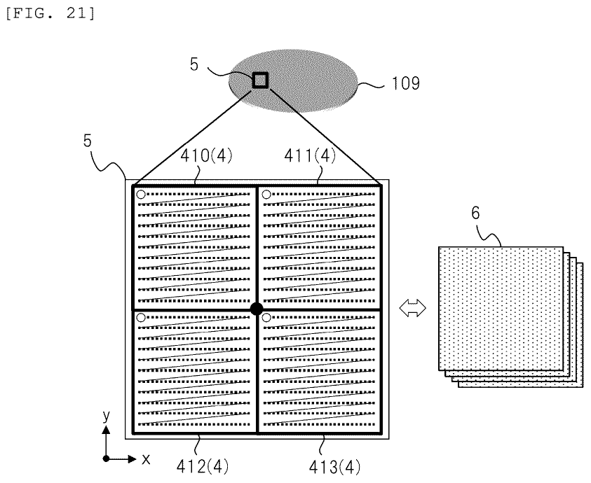

The stage 110 is a mechanism that can move in an X direction and a Y direction corresponding to, for example, an illustrated horizontal direction and a radial direction of a semiconductor wafer. Alternatively, the stage 110 may be a mechanism capable of moving in a Z direction corresponding to a vertical direction and perpendicular to the X direction and the Y direction, or may be a mechanism capable of rotating or tilting in each axial direction. Although details of implementation of the charged particle beam device 2 are not limited, the charged particle beam device 2 may be configured to emit multiple beams (FIG. 21 described later). Although the charged particle beam device 2 is illustrated as including one detector 121, the invention is not limited thereto, and the charged particle beam device 2 may include a plurality of detectors. For example, an SE detector that detects an SE and a BSE detector that detects a BSE may be provided. For example, a plurality of detectors may be installed at a plurality of positions. That is, a plurality of channels and a plurality of detection systems may be provided as a configuration for capturing an image. When generating an image, one image may be generated by performing processing such as integration on a plurality of images based on a plurality of signals repeatedly detected from the same region.

The sample 109 is, for example, a semiconductor wafer. When the sample 109 is irradiated with the charged particle beam 103, electrons 120 such as secondary electrons (SE) and backscattered electrons (BSE) are emitted from an inside of the sample 109. The emitted electrons 120 are accelerated by an acceleration action based on a negative voltage applied to the sample 109 and captured by the detector 121. The detection signal s1 output from the detector 121 is sent to the controller 200. The controller 200 receives the detection signal s1 through a communication device 201.

The controller 200 includes the communication device 201, a processor 202, a memory 203 such as a RAM or a non-volatile storage device, a display device 204, and an input and output device 205. These components are connected to each other by an architecture such as a bus. The controller 200 controls imaging by the main body 100 according to a set imaging recipe. The processor 202 generates an observation image based on the detection signal s1 obtained through the communication device 201, as an image in which the quantity of electrons captured by the detector 121 is luminance. The processor 202 stores data such as the generated observation image in the memory 203. The processor 202 sends the signal s2 corresponding to the generated data such as the observation image to the computer 3 through the communication device 201. The computer 3 receives the signal s2 through a communication device 310. A user U1 may operate the display device 204 and the input and output device 205 to use the controller 200.

The communication device 201 is a device in which a communication interface with the main body 100 and a communication interface with the computer 3 are implemented. Examples of the communication interface include, but are not limited to, a LAN. The input and output device 205 is an input device or an output device. The input device and the output device may be built-in or externally connected. Examples of the input device include a keyboard, a mouse, and a microphone. Examples of the output device include a display, a printer, and a speaker.

The computer 3 includes the communication device 310, a storage 320, a processor 330, a memory 331 such as a RAM or a non-volatile storage device, a display device 332, an input and output device 333, and the like. These components are connected to each other by an architecture such as a bus. The storage 320 is a memory having a relatively large-capacity storage area. The storage 320 stores a reference data DB 321, an evaluation target data DB 322, a device state DB 323, a device correction DB 324, and a device management program 325. The memory of the computer 3 also stores necessary management information and a database (DB). An external storage device, a server, or the like may be connected to the computer 3, necessary data and information may be stored in the external storage device, the server, or the like, and the data and information may be read and written as appropriate.

The communication device 310 is a device in which a communication interface with the controller 200 is implemented. An external device or the like may be connected to the computer 3 via a network such as a LAN. The input and output device 333 is an input device or an output device. The input device and the output device may be built-in or externally connected. Examples of the input device include a keyboard, a mouse, and a microphone. Examples of the output device include a display, a printer, and a speaker.

The user U1 of the observation system 1 operates the display device 332, the input and output device 333, and the like to use the computer 3. Accordingly, the user Ul uses the observation system 1. A display screen of the display device 332 displays a screen serving as a user interface of the observation system 1, in other words, a screen with a graphical user interface (GUI). The computer 3 may be implemented by a client-server system. In this case, the user Ul operates a PC or the like serving as a client terminal, and the PC or the like accesses the computer 3 serving as a server through communication.

The computer 3 is a part that executes characteristic processing in Embodiment 1. The computer 3 is connected to the controller 200. The controller 200 may be implemented as a part of the computer 3. The computer 3 may be implemented as a part of the controller 200. The controller 200 and the computer 3 may be implemented by an integrated computer system. The controller 200 may execute at least a part of the characteristic processing in Embodiment 1. An entire device including the computer 3 may be the charged particle beam device 2.

The processor 330 may be implemented with, for example, a CPU, a ROM, and a RAM. The memory 331 appropriately stores various kinds of data and information to be processed by the processor 330. The memory 331 stores, for example, a program execution module, image data, and processing result information. The device management program 325 also includes system setting information and user setting information. In addition to the illustrated DB, the storage 320 may store processing result information, history information, screen data, and the like.

The controller 200 grasps imaging field coordinate information of the main body 100. The controller 200 grasps a generation time when an image (for example, a reference image or an evaluation target image) is generated based on the detection signal s1, in other words, an imaging time. The controller 200 stores data and information such as the imaging field coordinate information, the image, and the generation time in the memory 203 in association with each other. When transmitting the signal s2 such as an image to the computer 3, the controller 200 transmits the signal s2 to the computer 3 as a series of data associated with the imaging field coordinate information, the image, the generation time, and the like. The computer 3 acquires and stores the series of associated data.

The imaging field coordinate information is information constituting a field of view when the surface of the sample 109 on the stage 110 of the main body 100 is irradiated with the charged particle beam 103 to perform imaging. This field of view corresponds to a region of an image to be captured.

The reference data DB 321 stores data such as a distribution of reference image quality evaluation values. The evaluation target data DB 322 stores data such as a distribution of calculated image quality evaluation values of an evaluation target. The device state DB 323 stores data of a correspondence relationship between a distribution of temporal variations in the image quality evaluation values and a device state. The device correction DB 324 stores data of a correspondence relationship between a device state and a correction portion and a correction portion.

The device management program 325 is a computer program that causes the computer 3 to execute processing, and is a program that implements a function of managing a state of the charged particle beam device 2 as a characteristic function of the observation system 1. The processor 330 reads the device management program 325 from the storage 320 into the memory 331 and executes processing according to the read program. Accordingly, characteristic functions and corresponding processing are implemented.

The observation system 1 and the computer system 3 are not limited to a configuration example of FIG. 1, and may be any system including one or more processors and one or more memories.

In a case of a form of the client-server system in relation to the computer 3, for example, the following operation is performed. The user U1 accesses the computer 3, which is a server, from a client terminal such as a PC via a network. The server provides a screen with a graphical user interface (GUI) to the client terminal. The server transmits GUI screen data (or may be, for example, a Web page) therefor to the client terminal. The client terminal displays a GUI screen on a display based on the received screen data. The user U1 views the GUI screen and inputs instructions, settings, and the like. The client terminal transmits input information to the server. The server executes processing in response to the received input information. For example, the server executes processing of evaluating a captured image and estimating a device state, stores a processing result, and transmits GUI screen data (only update information may be used) for displaying the processing result to the client terminal. The client terminal updates the display of the GUI screen based on the received screen data. The user U1 can check the processing result, for example, an estimation result of the device state by viewing the GUI screen.

As a supplement, FIG. 21 is a diagram illustrating an overview of imaging by scanning with the charged particle beam 103 when a plurality of images of a plurality of observation regions 4 are captured for a certain region 5 of the sample 109 by the charged particle beam device 2 which is an SEM. First, in a case of the SEM that uses a method of scanning each observation region 4 sequentially in time with a single charged particle beam 103, for example, at a first time, the observation region 410 is scanned with the charged particle beam 103, thereby obtaining a detection signal corresponding to the observation region 410. Similarly, at the next second time, an observation region 411 is scanned with the charged particle beam 103, thereby obtaining a detection signal corresponding to the observation region 411. At the next third time, a detection signal corresponding to an observation region 412 is obtained. At the next fourth time, a detection signal corresponding to an observation region 413 is obtained. Respective images 6 are obtained from the respective detection signals.

Meanwhile, when the charged particle beam device 2 is a multi-beam type SEM, the following is performed. Although not illustrated, the main body 100 in FIG. 1 includes a mechanism for generating a plurality of charged particle beams from a single beam source or a mechanism for generating a plurality of charged particle beams from a plurality of beam sources. The sample 109 is simultaneously irradiated with the plurality of generated charged particle beams. For example, four observation regions 4 (410 to 413) in FIG. 21 are simultaneously irradiated with four charged particle beams while being scanned. Accordingly, four detection signals corresponding to the four observation regions 4 (410 to 413) are obtained, and the respective images 6 are obtained based on the respective detection signals.

### Processing Flow of Device Management Program

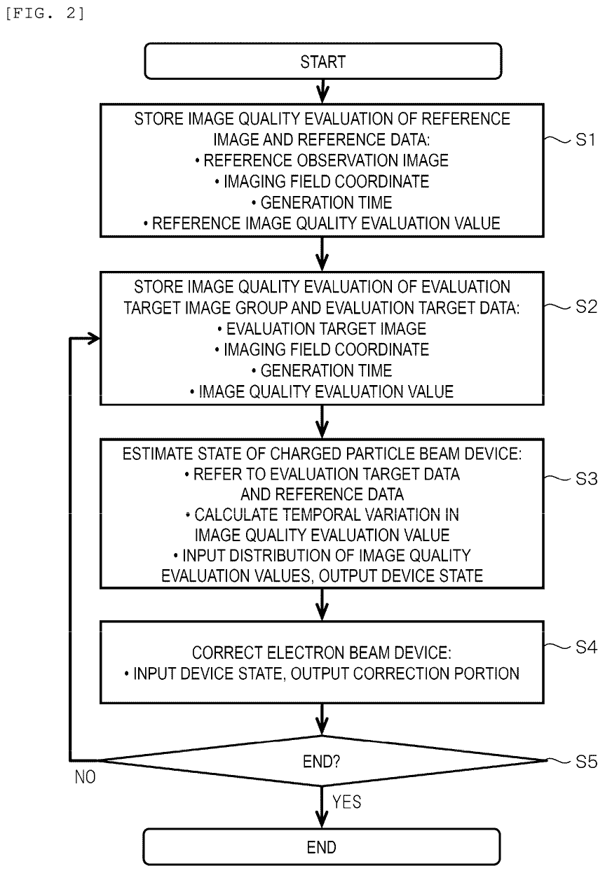

FIG. 2 illustrates a flow of a series of processing based on the device management program 325 by the computer 3 as main processing of the observation system 1.

First, step S1 is a step of storing image quality evaluation of a reference image and reference data. In step S1, based on drive control from the controller 200, the main body 100 of the charged particle beam device 2 sets an imaging field, emits the charged particle beam 103 so as to scan an observation region of the sample 109 corresponding to the imaging field, and outputs the detection signal s1 captured by the detector 121 to the controller 200. At the same time, the main body 100 sends, to the controller 200, imaging field coordinates indicating a relative position between the charged particle beam device 2 and the observation region when the observation region corresponding to the imaging field is moved using deflection by the image shift deflector 106 without moving the stage 110. Alternatively, when the controller 200 grasps such imaging field coordinates based on its own control, the controller 200 does not need to receive the imaging field coordinates from the main body 100.

The controller 200 generates, for example, a reference image as the observation image by processing of the processor 202 based on the sent detection signal s1. The controller 200 sends the signal s2 of the image data in which the generated reference image, the imaging field coordinate, and the generation time are associated with each other to the computer 3 through the communication device 201.

The processor 330 of the computer 3 calculates a reference image quality evaluation value for each predetermined region in the reference image based on the sent data signal s2. The processor 330 stores the reference image, the generation time, the imaging field coordinate, and the calculated distribution of the reference image quality evaluation values in association with each other in the reference data DB 321 as reference data.

Step S2 is a step of storing image quality evaluation of an evaluation target image group and evaluation target data. In step S2, based on control of the controller 200, the main body 100 of the charged particle beam device 2 emits the charged particle beam 103 so as to scan different observation regions of the sample 109 corresponding to different imaging fields, that is, each observation region of a plurality of observation regions, and sends the detection signal s1 captured by the detector 121 to the controller 200. The main body 100 sends the imaging field coordinate of the observation region to the controller 200. Alternatively, when the controller 200 grasps the imaging field coordinate by itself, the controller 200 does not need to acquire the imaging field coordinate from the main body 100.

The controller 200 generates a plurality of evaluation target images as the observation image by the processor 203 based on the detection signal s1 and the like, and stores, in the memory 203, an evaluation target image group including the plurality of generated evaluation target images, imaging field coordinates corresponding to the evaluation target images, and an evaluation target time that is a generation time of the image in association with each other. The controller 200 sends the signal s2 of data of the evaluation target image group, the imaging field coordinate, and the evaluation target time to the computer 3 through the communication device 201. The computer 3 receives the data and stores the data in the memory 331. The processor 330 of the computer 3 calculates an image quality evaluation value for each predetermined region of each evaluation target image in the evaluation target image group. The processor 330 stores the evaluation target image, the calculated distribution of the image quality evaluation values, the imaging field coordinate, and the evaluation target time in association with each other in the evaluation target data DB 322 as the evaluation target data.

Step S3 is a step of estimating a state of the charged particle beam device 2. In step S3, the processor 330 of the computer 3 reads, from the evaluation target data DB 322, evaluation target data corresponding to an evaluation period including an evaluation time at which the state of the charged particle beam device 2 is estimated. The processor 330 reads, from the reference data DB 321, the reference data corresponding to the imaging field coordinate in the read evaluation target data. The processor 330 compares the read evaluation target data and reference data for each of the corresponding predetermined regions in the data, and calculates a temporal variation in the image quality evaluation value. The processor 330 inputs a distribution of temporal variations in the image quality evaluation values to the device state DB 323, and outputs the “device state” representing a state of the charged particle beam device 2 at the generation time of the evaluation target image.

Step S4 is a step of correcting the charged particle beam device 2. In step S4, the device state output in step S3 is input to the device correction DB 324 to output a correction portion of the charged particle beam device 2 that reduces the temporal variation in the image quality evaluation value with respect to the reference data.

In step S5, the computer 3 checks whether the processing ends, and when the processing does not end and monitoring and evaluation of the device state of the charged particle beam device 2 are continued (NO), the computer 3 returns to step S22 and repeats the processing in the same manner, thereby continuing the monitoring and evaluation of the device state of the charged particle beam device 2.

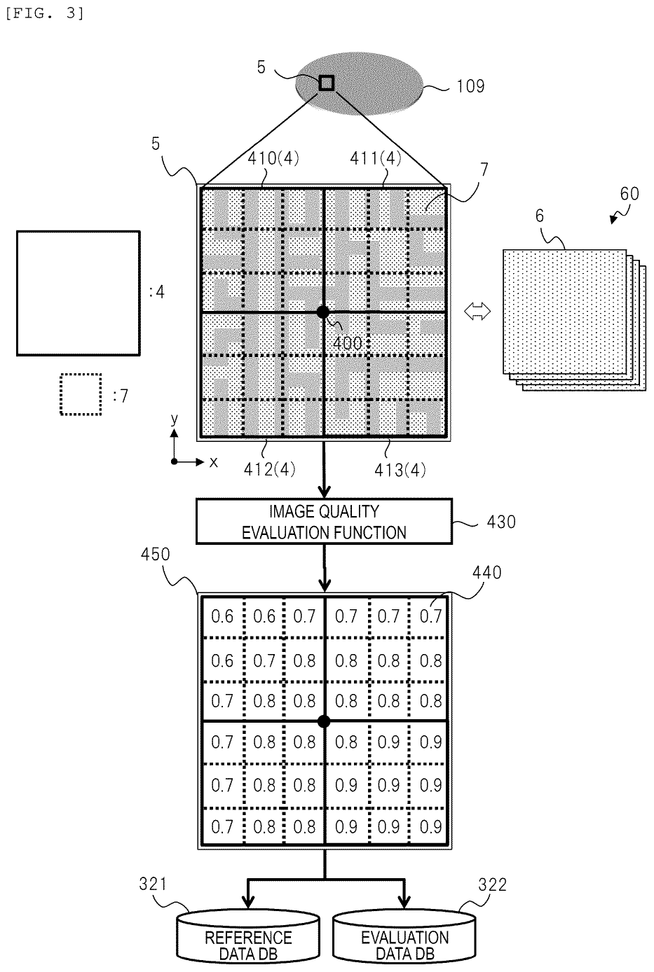

Hereinafter, in FIG. 3 and subsequent drawings, specific examples of estimation, correction, and the like of the device state of the charged particle beam device 2 will be described assuming a case where a semiconductor wafer is observed as the sample 109 while managing the device state of the charged particle beam device 2 in the observation system 1.

### Image Quality Evaluation Method of Observation Image

FIG. 3 is a diagram of an image quality evaluation method of an observation image in an observation region on a semiconductor wafer surface as the sample 109. The charged particle beam device 2 in FIG. 1 acquires a plurality of images 6 in a plurality of observation regions 4 in an observation region 5 that is a certain region 5 of the sample 109 by moving a scanning region of the charged particle beam 103 corresponding to an imaging field by the image shift deflector 106. The image 6 is, for example, the evaluation target image. For example, an evaluation target image group 60 that is the plurality of images 6 is acquired. One imaging field corresponds to one observation region 4. One observation region 4 corresponds to one image 6. In the example in FIG. 3, the four observation regions 4 include a first observation region 410, a second observation region 411, a third observation region 412, and a fourth observation region 413. The evaluation target image group 60 may be one or more images 6. A center 400 indicates a center point of the observation region 5 in an X direction and a Y direction.

In Embodiment 1, the plurality of images 6 of the evaluation target image group 60 are acquired sequentially in time based on the single charged particle beam 103 (FIG. 21), but the invention is not limited thereto. When the charged particle beam device 2 is a multi-beam type device, a plurality of images 6 of the evaluation target image group 60 may be simultaneously acquired by simultaneously scanning and irradiating the sample 109 with a plurality of charged particle beams.

The computer 3 divides each observation region 4 corresponding to the image 6 into predetermined regions 7. In this example, a size of the predetermined region 7 is smaller than a size of the observation region 4. In the example in FIG. 3, one observation region 4 is divided into a plurality of (for example, three) regions in a horizontal direction, which is the x direction, and into a plurality of (for example, three) regions in a vertical direction, which is the y direction. A shape of the predetermined region 7 is a square having the same size in the x direction and the y direction.

The computer 3 divides the observation region 4 of the image 6 into a plurality of predetermined regions 7. The predetermined region 7 is a region serving as a unit for calculating the image quality evaluation value. That is, one image quality evaluation value is calculated for one predetermined region 7. In order to obtain the distribution of the image quality evaluation values in a two-dimensional space (that is, an x-y plane), it is essential to implement the distribution of the plurality of predetermined regions 7 in the two-dimensional space.

The computer 3 inputs each predetermined region 7 of each image 6 into the image quality evaluation function 430 to obtain an image quality evaluation value 440 for each predetermined region 7. An image quality evaluation result 450 illustrates an example of the image quality evaluation value 440 in the observation region 5.

The computer 3 associates the image quality evaluation value 440 of the image quality evaluation result 450, the evaluation target image 6 which is the image 6 corresponding thereto, the imaging field coordinate, and the evaluation target time which is a generation time of the image 6, and stores the data in the evaluation target data DB 322 as the evaluation target data. The computer 3 may store the data in the reference data DB 321 as the reference data. The computer 3 may store the data in at least one of the DBs. The computer 3 may store reference data including the image 6 as the reference image, or may store evaluation target data including the image 6 as the evaluation target image.

The imaging field coordinate is a value representing a relative position between the charged particle beam device 2 and the observation region when the observation image is acquired without moving the stage 110. The computer 3 may store the evaluation target data obtained during an operation of the observation system 1 in the reference data DB 321 as reference data. When the above data is stored as reference data in the reference data DB 321, the image quality evaluation value 440 is not limited to being calculated in an observation image generated based on a signal obtained by the charged particle beam device 2, and may be an image quality evaluation value obtained by simulation. The acquisition of the observation image indicates that the controller 200 generates the observation image based on the signal s1 output by the detector 121 or the computer 3 receives the observation image from the controller 200.

One observation region 4 is a region corresponding to one imaging field. Depending on a configuration of the charged particle beam device 2, the imaging field and the observation region 4 can be moved by controlling movement of the stage 110, or the imaging field and the observation region 4 can be moved by deflecting the charged particle beam 103 without moving the stage 110. Either of the above may be used.

In Embodiment 1, the plurality of images 6 corresponding to the plurality of observation regions 4 are set as evaluation targets in order to cover a wide region of the surface of the sample 109. In other words, this is to cover a necessary and sufficient region in order to estimate a state of a component part (for example, a beam irradiation system) of the charged particle beam device 2. As a modification, only one observation image may be targeted.

### Predetermined Region

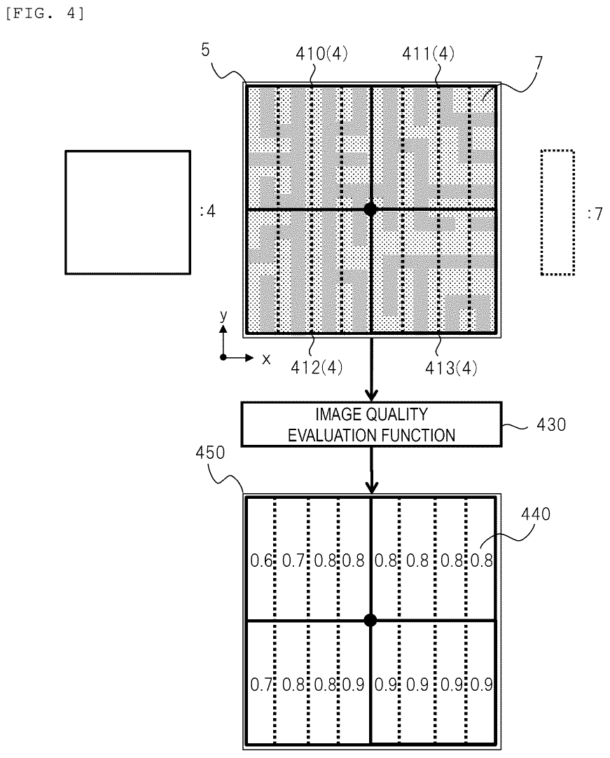

FIG. 4 is another example of a shape of the predetermined region 7, in other words, a divided region, an image quality evaluation value calculation region. A shape when the observation region 4 is divided into the predetermined regions 7 is any shape. In the example in FIG. 3, the predetermined region 7 has a square shape, in other words, a rectangle or a lattice shape, but the shape is not limited thereto, and may be, for example, as in the example in FIG. 4. In the example in FIG. 4, the shape of the predetermined region 7 is a vertical stripe shape in which a size in the y direction, which is the vertical direction, is longer. In the example in FIG. 4, one observation region 4 is divided into a plurality of (for example, four) regions in the x direction, and is not divided in the y direction. Other examples of the shape of the predetermined region 7 may include a circle and a polygon. As long as a two-dimensional distribution of the predetermined region 7 is obtained, various settings can be made.

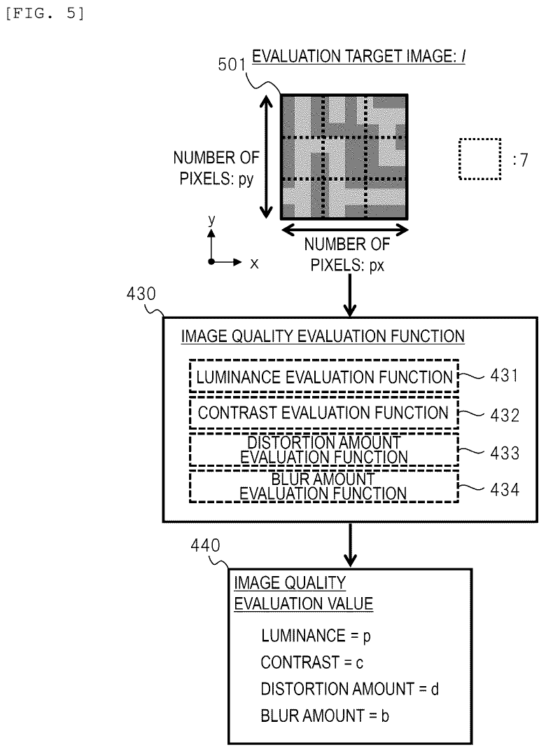

The number, size, and shape of the predetermined regions 7 may be defined according to a type of the image quality evaluation value, in other words, a parameter. A shape or the like suitable for calculation may be defined according to the image quality evaluation value. In other words, the suitable predetermined region 7 may be selected according to the respective image quality evaluation value. A method of dividing and setting the predetermined region 7, that is, the shape, size, number, and the like of the predetermined region 7 may be different for each image quality evaluation value (for example, luminance, contrast, distortion amount, and blur amount in FIG. 5).

### Image Quality Evaluation Function

FIG. 5 is a diagram of the image quality evaluation function 430. The computer 3 inputs an evaluation target image 501 (evaluation target image: I) as a target of image quality evaluation to the image quality evaluation function 430. The evaluation target image 501 has the number of pixels in the x direction px and the number of pixels in the y direction py, and corresponds to the observation region 4 or the predetermined region 7 in FIG. 3. At this time, the image quality evaluation function 430 calculates an image quality evaluation value for each image in each predetermined region 7 in FIG. 3. The computer 3 outputs the image quality evaluation value 440 using at least one of a luminance evaluation function 431, a contrast evaluation function 432, a distortion amount evaluation function 433, and a blur amount evaluation function 434 as the four functions in the image quality evaluation function 430. The image quality evaluation value 440 is at least one of luminance, contrast, distortion amount, and blur amount.

The luminance evaluation function 431 is a function for calculating an average of luminance values of the evaluation target image. The contrast evaluation function 432 is a function for calculating a ratio of a difference between a maximum value and a minimum value of the luminance values of the evaluation target image to a sum of the maximum value and the minimum value of the luminance values. The distortion amount evaluation function 433 is a function for calculating, as a relative distortion amount with respect to the reference observation image, a distortion intensity when a difference between the evaluation target image and an image obtained by adding distortion to the reference observation image including the same observation region as the evaluation target image while changing the distortion intensity is minimized. The blur amount evaluation function 434 is a function for calculating a blur intensity that reduces a difference between an evaluation target image and a blurred image created by applying blur removal processing to the evaluation target image to create a sharp image, and then changing the blur intensity of processing that blurs an image using Gaussian blur or the like.

A calculation method of the four functions 431, 432, 433, 434 in the image quality evaluation function 430 is an example. The invention is not limited thereto, and other calculation methods may be used. The image quality evaluation function 430 may be used to calculate a reference image quality evaluation value stored as reference data.

The blur amount evaluation function 434 may be a function for calculating the blur amount in each of the horizontal direction (for example, the x direction) and a vertical direction (for example, the y direction) of the image. For example, in the charged particle beam 103 passing off-axis of the objective lens 108 in FIG. 1, astigmatism, which is one of off-axis aberrations having different image formation distances in the horizontal direction and the vertical direction, occurs, and the observation image is an image having different blur amounts in the horizontal direction and the vertical direction. By calculating the blur amount for each direction using the blur amount evaluation function 434 and comparing the blur amounts in two directions, the horizontal direction and the vertical direction, an astigmatism amount and a direction of the astigmatism can be evaluated.

### Distribution for Temporal Variations in Image Quality Evaluation Values in Predetermined Region

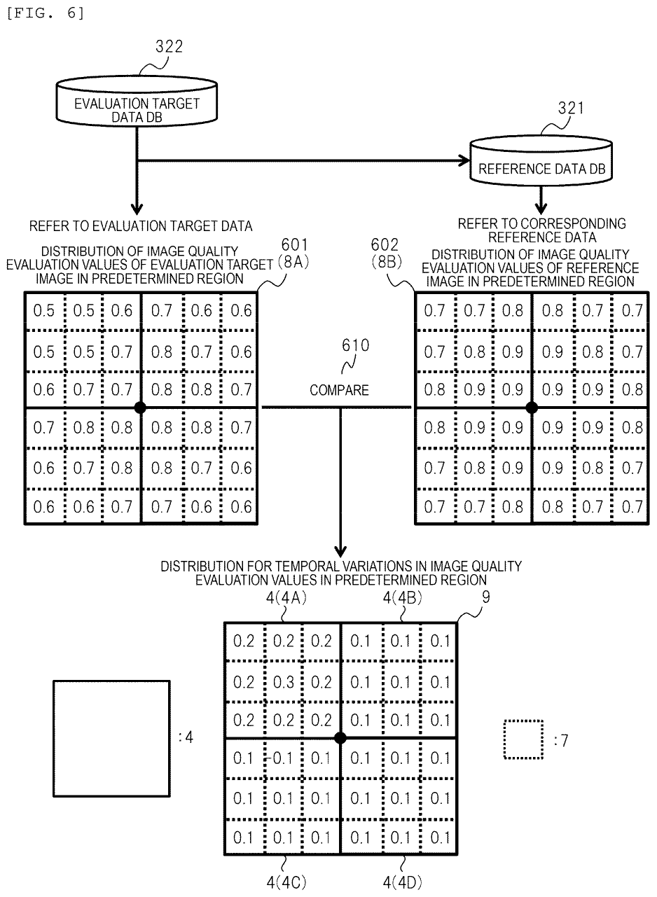

FIG. 6 is a diagram of a distribution for the temporal variations in the image quality evaluation values in the predetermined region. The computer 3 refers to evaluation target data 601 generated in an evaluation period including an evaluation time at which the device state is estimated from the evaluation target data DB 322, in other words, a distribution 8A of the image quality evaluation values of the evaluation target images in the predetermined region. The computer 3 refers to, from the reference data DB 321, reference data 602 having the same method of dividing the predetermined region 7 and including the image quality evaluation value as a reference of the device state, in other words, a distribution 8B of the image quality evaluation values of the reference images in the predetermined region with respect to the evaluation target data 601 referred to. The computer 3 obtains a distribution 9 for the temporal variations in the image quality evaluation values in the predetermined region by processing 610, which compares the distribution 8A of the image quality evaluation values of the referred evaluation target data 601 with the distribution 8B of the reference image quality evaluation values of the referred reference data 602 to calculate a difference. The distribution 9 has a value of a temporal variation in the image quality evaluation value for each predetermined region 7. The computer 3 compares the image quality evaluation value of the reference image in the predetermined region 7 with the image quality evaluation value of the evaluation target image in the predetermined region 7 whose position and size correspond to the image quality evaluation value of the reference image in the predetermined region 7, for example, calculates a temporal variation in the image quality evaluation value by a difference operation.

In this example, in the distribution 9, in an upper right, lower left, and lower right observation regions 4B, 4C, and 4D among the regions corresponding to the observation region 5 in FIG. 3, a value of the temporal variation in the image quality evaluation value in each predetermined region 7 is 0.1. Meanwhile, in an upper left observation region 4A, a value of the temporal variation in the image quality evaluation value in the predetermined region 7 is 0.3 in a central predetermined region 7 among a 3×3 grid, and is 0.2 in the other predetermined regions 7.

A temporal variation refers to a variation corresponding to a time difference from a time point of a generation time at which the reference data is generated in the past to a time point of an evaluation time at which the evaluation target data is generated. Since the temporal variation in the image quality evaluation value is obtained in each predetermined region 7, when viewed on the two-dimensional x-y plane, a distribution of the temporal variations in the image quality evaluation values is obtained. In the period of this temporal variation, a state of the charged particle beam device 2 may change due to various factors. Examples thereof include a positional deviation of a component, a change in electrical characteristics, and deterioration of a member due to a use time, vibration, or the like.

### Estimation of Device State

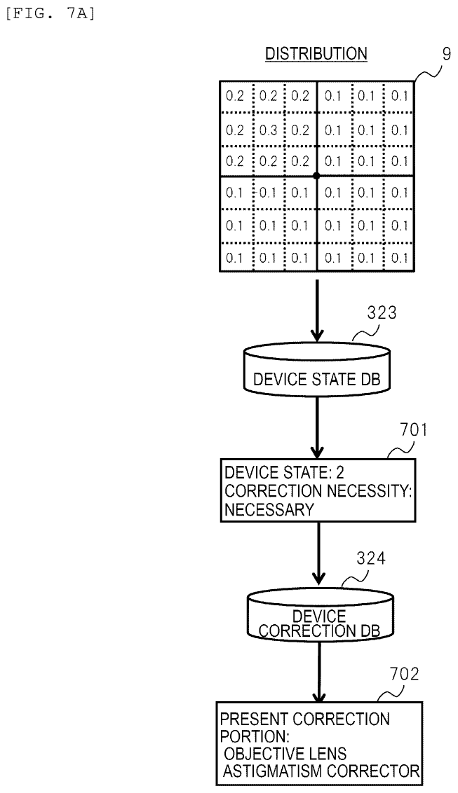

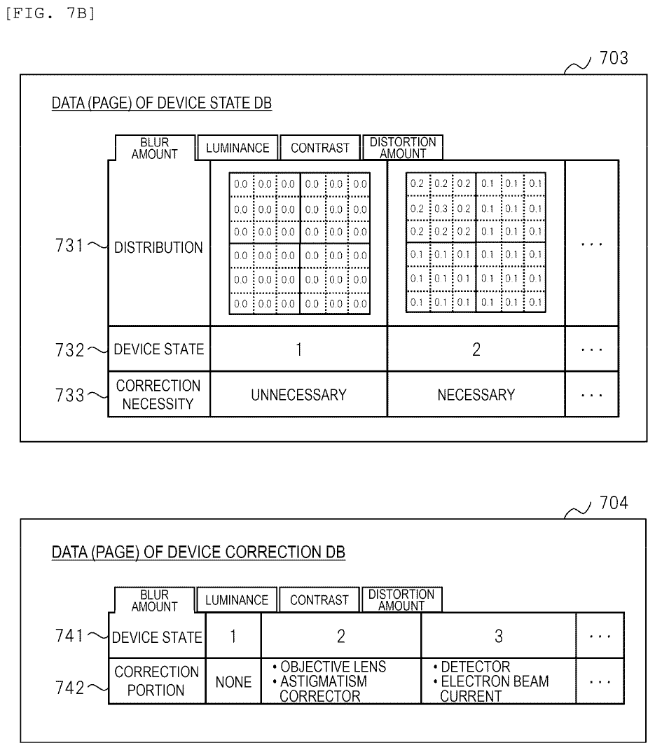

FIGS. 7A and 7B are diagrams of estimation of the device state using the device state DB 323 from the distribution 9. FIG. 7A illustrates that an output 701 of the device state and the correction necessity is acquired from the distribution 9 with reference to the device state DB 323, and the output 702 of the correction portion is acquired from the output 701 with reference to the device correction DB 324. FIG. 7B illustrates an example of data 703 in the device state DB 323 and an example of data 704 in the device correction DB 324.

As illustrated in FIG. 7B, the device state DB 323 includes the separate page data 703 for each function of the functions 431 to 434 in the image quality evaluation function 430 or for each combination of the functions. In each page, a distribution 731 for the temporal variation in the image quality evaluation value in a predetermined region, a label value 732 indicating the device state, and correction necessity 733 for the device state are stored in association with each other. In FIG. 7B, only the page of the blur amount evaluation function 434 is illustrated, but pages for other functions are also available similarly.

The computer 3 compares the distribution 9 for the temporal variations in the image quality evaluation values in the predetermined region with the distribution 731 stored in the page of the image quality evaluation function corresponding to the device state DB 423, thereby searching for the distribution 731 having the smallest difference. The computer 3 outputs the label value 732 indicating the device state associated with the distribution 731 having the smallest difference as a result of the search and the correction necessity 733. In the example in FIG. 7A, in the output 701, the label value indicating the device state is 2, and the correction necessity is necessary. When the output correction necessity is necessary, the computer 3 inputs the label value indicating the device state to the device correction DB 324, and obtains a correction portion for reducing the temporal variation in the image quality evaluation value as an output.

As illustrated in FIG. 7B, in the device correction DB 324, there is a separate page for each function of the functions 431 to 434 in the image quality evaluation function 430 or for each combination of the functions. In each page, a label value 741 indicating the device state and a correction portion 742 are stored in association with each other. For example, there are an objective lens and an astigmatism corrector as correction portions corresponding to the device state with the label value=2.

In the device state DB 323, a correspondence relationship between the distribution 731 of temporal variations in the image quality evaluation values and the device state 732 is stored as data and information. Therefore, information such as the device state is obtained as the output 701 from the device state DB 323 with respect to the distribution 9 which is the input. The device correction DB 324 stores a correspondence relationship between the device state 741 and the correction portion 742 as data and information. Therefore, information such as a correction portion is obtained as the output 702 from the correction DB 324 with respect to information such as the device state which is an input. In the device correction DB 704 in FIG. 7B, as the correction portion 742 associated with the device state 741 and the distribution 731 associated therewith, a correction portion for reducing the temporal variation in the image quality evaluation value, in other words, a difference between the reference image quality evaluation value and the image quality evaluation value of the evaluation target, in other words, a preferential correction candidate portion is described.

For example, when the blur amount for each direction is calculated as the image quality evaluation value using the blur amount evaluation function 434 in FIG. 5, it is possible to estimate a temporal variation in the blur amount for each direction for each predetermined region 7. The computer 3 can grasp the difference in image formation distance between the horizontal direction and the vertical direction of the objective lens 108 in FIG. 1 by comparing the blur amount for each direction. Therefore, the computer 3 can correct a parameter of the objective lens 108 or a parameter of the astigmatism corrector 105 in FIG. 1 so as to reduce a temporal variation from the generation time of the reference data. The computer 3 may determine a correction amount according to a time difference between the generation time of the reference data and the evaluation target time of the evaluation target data.

In other words, the label value indicating the device state in FIGS. 7A and 7B is a classification value when the distribution 9 of the temporal variations in the image quality evaluation values and a mode of the distribution 9 are grasped as a mathematical pattern or the like. In this example, the label value for the device state is a number such as 1, 2, 3, but this is merely identification information, may be freely set, and does not represent a degree of change or the like.

Details of the device state DB 323 and the correction DB 324 are not limited, but as an implementation example, a designer/operator of the device management program 325 or the like of the observation system 1 may set the contents of these DBS. Although the device state DB 323 and the device correction DB 324 are separately provided, the invention is not limited thereto, and these may be integrated into one DB. For example, when the data 703 of the device state DB in FIG. 7A and the data 704 in the device correction DB in FIG. 7B are integrated into one DB, the one DB stores the association between the distribution, the device state, the correction necessity, and the correction portion.

In FIG. 7B, the computer 3 compares the distribution 9 for the temporal variations in the image quality evaluation values in the predetermined region with each distribution 731 in the device state DB 323, and searches for and extracts the distribution 731 with the smallest difference therebetween as the closest distribution. In this case, a specific example of the calculation of the difference, in other words, the distribution difference is as follows. The computer 3 calculates a difference in value between the predetermined regions 7 corresponding in position among the distributions, and calculates a total value of the differences in value between the predetermined regions 7 of the plurality of predetermined regions 7. The computer 3 determines that the distribution 421 having the smallest total value is the closest distribution.

### User Interface

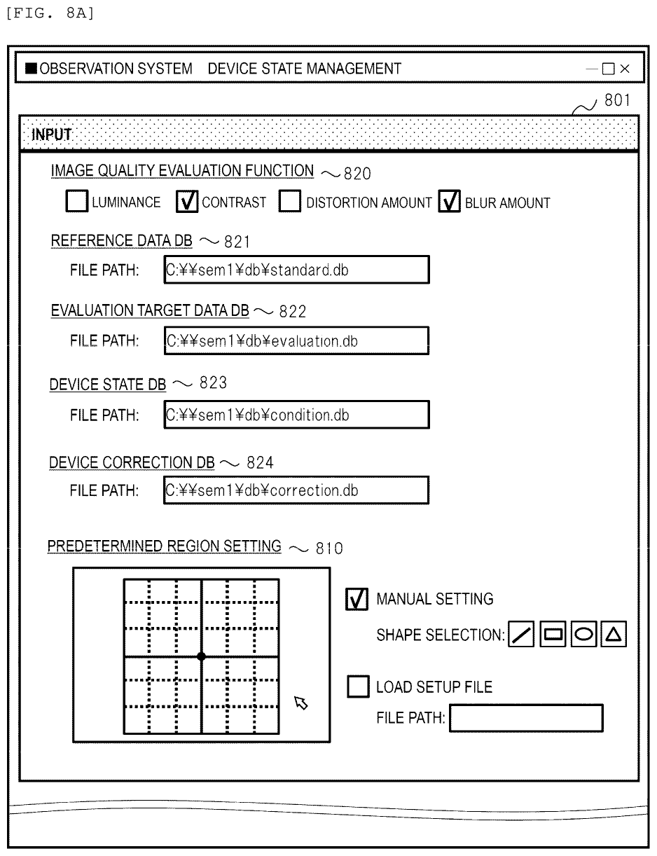

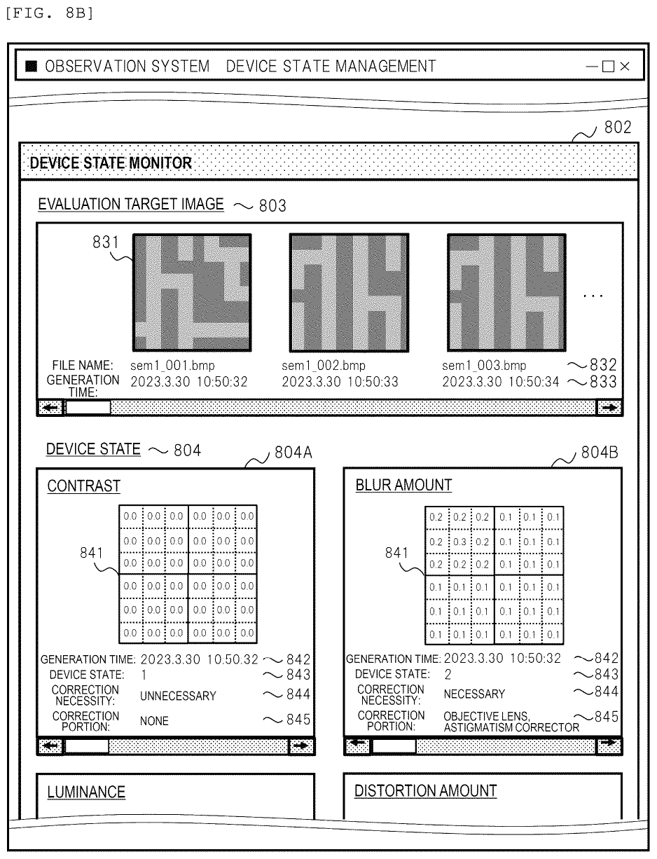

FIGS. 8A and 8B illustrate examples of user interfaces, particularly GUI screens, displayed on a display screen of the display device 204 of the controller 200 or on the display screen of the display device 332 of the computer 3 in FIG. 1. FIG. 8A illustrates a first half of the screen, and FIG. 8B illustrates a second half of the screen. The GUI screen may be provided, for example, as an application window or as a Web page.

In FIG. 8A, the GUI screen includes an input field 801. The input field 801 is a field for inputting parameters for executing the device management program 325 according to an input operation by the user Ul using the input and output device 205 or the input and output device 333 in FIG. 1. The input field 801 includes an image quality evaluation function checkbox 820, a reference data DB file path input field 821, an evaluation target data DB file path input field 822, a device state DB file path input field 823, and a device correction DB file path input field 824. The image quality evaluation function checkbox 820 is a checkbox for selecting a function to be used from the functions in the image quality evaluation function 430. The reference data DB file path input field 821 is an input field for a file path indicating a location of the reference data DB 321 on the storage. Similarly, the evaluation target data DB file path input field 822 is an input field of a file path of the evaluation data DB 322, the device state DB file path input field 823 is an input field of a file path of the device state DB 323, and the device correction DB file path input field 824 is an input field of a file path of the device correction DB 324.

The input field 801 includes a predetermined region setting field 810. In the predetermined region setting field 810, the predetermined region 7 described above can be set for the observation region of the image. In other words, a method of dividing the predetermined region 7 described above can be set. This setting can be selected from manual setting by the user U1 and loading setup file. In the manual setting, the user U1 can select a shape and set the predetermined region 7 with the selected shape. For example, it is possible to draw a line or surround the line with a rectangle. Alternatively, although not illustrated, vertical and horizontal widths, the number of divisions, and the like of the predetermined region 7 may be input. The user U1 can set a suitable predetermined region 7 according to the image quality evaluation value, for example, including the examples in FIGS. 3 and 4. Thus, on the GUI screen, the user can set the predetermined region 7 for each image quality evaluation value, in other words, for each image quality evaluation function corresponding thereto. It is also possible to set and apply a common predetermined region 7 regardless of the image quality evaluation value.

In FIG. 8B, the GUI screen includes a device state monitor field 802 for displaying an execution result of the device management program. The device state monitor field 802 includes an evaluation target image list field 803 and a device state field 804. In the evaluation target image list field 803, a list of an evaluation target image 831 acquired by the charged particle beam device 2 and a file name 832 and a generation time 833 of the image is displayed.

In the device state field 804, for each item (for example, luminance, contrast, distortion amount, and blur amount) selected in the image quality evaluation function checkbox 820 in the input: field 801, a distribution 841 for temporal variations in a predetermined region, a generation time 842, a label value for a device state 843, correction necessity 844, and a correction portion 845 are displayed. In this example, since the contrast and the blur amount are selected, information is displayed in a contrast field 804A and a blur amount field 804B.

As a modification, a display of the distribution 841 is not limited to the display of the numerical value, and an expression may be changed such as replacing the numerical value with a color. The label value for the device state 843 is not limited to display of a numerical value, and may be display of a natural language. The correction necessity 844 is not limited to a binary value of necessary or not, and may be a multi-stage value, or may display a time to be corrected, a time to recommend correction, and the like. The correction portion 845 is not limited to a name of a component of the charged particle beam device 2, and a portion and position may be graphically displayed in a configuration diagram or the like. A link may be attached to the correction portion, and when the user U1 operates the link, the screen may transition to a setting screen of the correction portion, and detailed setting work for the correction portion may be performed.

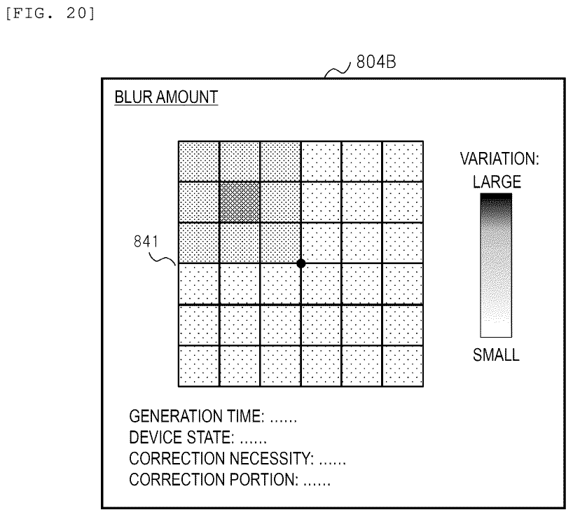

FIG. 20 illustrates, as a modification, an example in which the distribution 841 is displayed on the GUI screen in an expression in which a numerical value is replaced with a color. In the distribution 841, the larger the temporal variation in the image quality evaluation value is, the darker the color is displayed.

### Effects, etc. of Embodiment 1

As described above, according to Embodiment 1, the state of the charged particle beam device 2 can be suitably managed. In particular, the user Ul can check, on the screen, the distribution of the temporal variations in the image quality evaluation values, the correction necessity according to the device state, and the correction portion. Therefore, the user Ul can more easily and suitably perform correction work of the charged particle beam device 2 than in the related art.

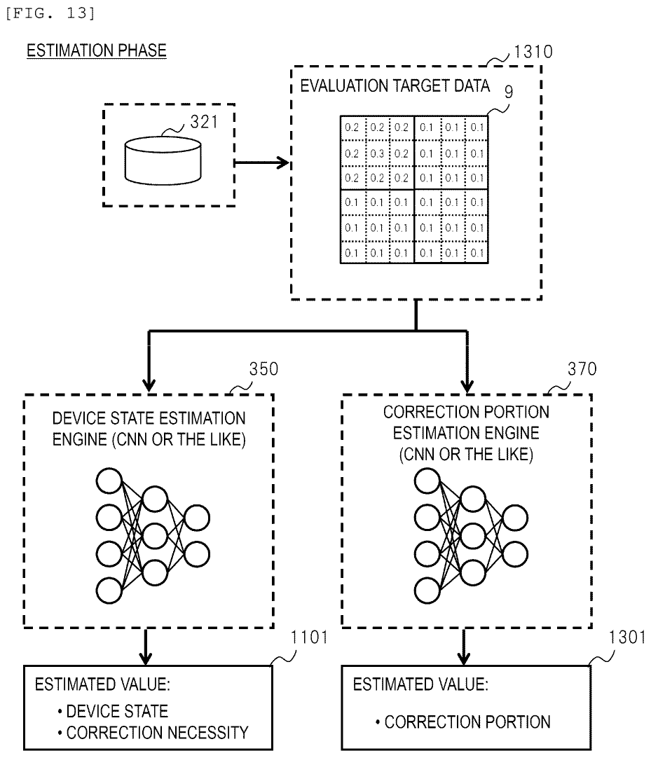

As an example, as illustrated in FIGS. 13A and 13B, when a function and parameter of image quality evaluation are the blur amount, a distribution 510 for the temporal variations in the image quality evaluation values in the predetermined region similar to FIG. 6 is obtained and displayed as the distribution 841 in the blur amount field 804B. The label value for the device state is 2, the correction necessity is necessary, and the correction portion is displayed as the objective lens and the astigmatism corrector. By looking at these, the user U1 can see that the state of the charged particle beam device 2 is a state in which correction is necessary, and specifically, it is understood that the objective lens 108 and the astigmatism corrector 105 in FIG. 1 are preferentially corrected. From the distribution 841 (similar to the distribution 9 in FIG. 6), it can be seen that a variation in the blur amount is relatively large in an upper left region of the image. This corresponds to, for example, a possibility that an irradiation axis of the charged particle beam 103 deviates from a center. Therefore, it can be seen that by checking and adjusting the objective lens 108 and the astigmatism corrector 105, correction is performed so that the irradiation axis of the charged particle beam 103 does not deviate from the center. Therefore, management and correction work by the user Ul for suitably maintaining the state of the charged particle beam device 2 can be facilitated and made efficient.

In Embodiment 1, as illustrated in FIGS. 8A and 8B, the distribution 841 and the distribution 9 for the temporal variations in the image quality evaluation values in the predetermined region in FIG. 6 are output to the user U1. The user U1 can check the distribution 841 on the GUI screen. The device state 843, the correction necessity 844, and the correction portion 845 are output on the GUI screen. The user Ul can view and confirm the information on the GUI screen. The user U1 can more easily and more efficiently perform the work of checking and correcting the state of the charged particle beam device 2 based on the information, in other words, support information than in the related art.

In Embodiment 1, as a feature, the state of the charged particle beam device 2, the correction portion, and the like are estimated based on the distribution 9 of the temporal variations in the image quality evaluation values, in other words, a two-dimensional distribution corresponding to the predetermined region 7. The inventors focus on the fact that there is a correspondence relationship between the image quality evaluation value, a mode such as whether the distribution 9 is uniform and where a change center is biased, and the device state, the correction portion, and the like, and consider a new mechanism described above for estimating the device state and the like using a correspondence relationship.

The following is also possible as a modification of Embodiment 1. In Embodiment 1, the reference image is also stored in association with the reference data DB 321, the evaluation target image is also stored in association with the evaluation target data DB 322, and the image can also be confirmed on the screen as necessary, but the invention is not limited thereto. At least data related to the image quality evaluation value needs to be stored, and the reference image and the evaluation target image may not be stored.

In Embodiment 1, as described above, the data related to the reference is registered in the reference data DB 321, and the data related to the evaluation target is registered in the evaluation target DB 322. The invention is not limited to this, and it is also possible to register data related to the evaluation target that is already evaluated in the reference data DB 321 as new reference data. In other words, registration data in the evaluation target DB 322 may be copied/migrated into the reference data DB 321 as the reference data.

The reference image quality evaluation value of the reference image of the reference data is not limited to being generated based on a captured image of the charged particle beam device 2, and may be generated based on simulation without imaging. For example, the computer 3 or any device in the observation system 1 may generate an ideal image quality evaluation value by simulation calculation or the like based on design data of the sample 109 and use the ideal image quality evaluation value as the reference data. For example, the computer 3 may refer to design data of the sample 109 from a manufacturing execution system (MES), a server, or the like connected to the observation system 1, and generate an ideal image quality evaluation value based on the design data by simulation calculation.

In Embodiment 1, as described above, the above-described predetermined region 7 for the observation image, in other words, a divided region and an image quality evaluation value calculation region can be set in the predetermined region setting field 810 on the GUI screen. The invention is not limited thereto, and in the system, the device, the method, the device management program 325, and the like according to the present embodiment, the predetermined region 7 corresponding to the image quality evaluation value or the like may be defined in advance as a design matter.

The computer 3 also performs data management for a method of dividing the predetermined region 7 in the image, in other words, a method of setting the predetermined region 7. For example, the computer 3 may store data and information such as the method of dividing the predetermined region 7 with respect to the image in association with the image or the DB. Data and information such as the method of dividing the predetermined region 7 may be added as attribute information/metadata of the image. As an example of the method of dividing the predetermined region 7, in the example in FIG. 3, a basic shape may be a rectangle, and a size in the x direction and the size in the y direction of the rectangle may be designated. Alternatively, the number of divisions in the x direction and the number of divisions in the y direction may be designated for the observation region 4.

In Embodiment 1, the computer 3 outputs up to the correction portion 845 to the user U1 on the GUI screen. As a modification, the computer 3 may automatically determine correction content information corresponding to the correction portion 845 and output the correction content information on the GUI screen. For example, when the correction portion 845 is the objective lens 108 in FIG. 1, the correction content information is information about which parameter of the objective lens 108 is to be corrected and how. The correction content information is, for example, information indicating a correction amount for an optical axis position as a parameter of the objective lens 108, in what direction and at what distance on the x-y plane. The correction content information may be correction instruction information or may be reference information serving as a guide for correction. In the example of the distribution 9 in FIG. 6 or the distribution 841 in the blur amount field 804B in FIG. 8B, since a value in an upper left region overall is relatively large, the correction amount may be set such that the optical axis position of the objective lens 108 is adjusted in a lower right direction.

In Embodiment 1, as illustrated in FIG. 6, a case where a region of the reference image and a region of the evaluation target image to be compared are the same, that is, a case where the imaging field coordinate, a size, and the like of images are the same and pattern structures captured in the observation region are the same has been described as a premise. The invention is not limited thereto, and the features described in Embodiment 1 can be similarly applied to a case where the region of the reference image and the region of the evaluation target image to be compared are different, in other words, a case where there is a deviation in the pattern structure captured in the observation region. This will be described later in Embodiment 4.

In Embodiment 1, it is assumed that the predetermined region 7 is smaller in size than the observation region 4 corresponding to the image 6, in other words, a plurality of predetermined regions 7 are in one observation region 4, but the invention is not limited thereto. In the modification, the predetermined region 7 may have a size equal to or larger than the size of the observation region 4. Adjacent predetermined regions 7 may have an overlapping portion. Even in such a case, a distribution of the plurality of predetermined regions 7 in the two-dimensional space may be obtained.

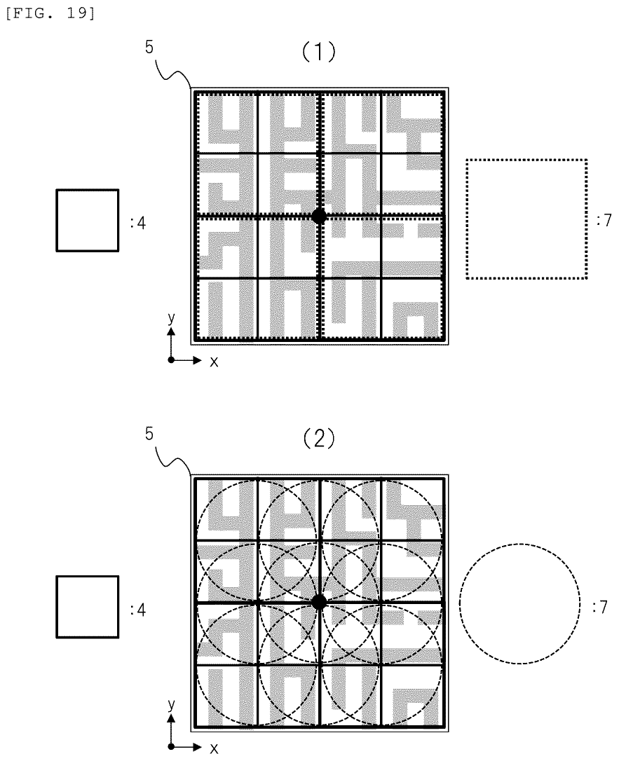

FIG. 19 illustrates an example of the predetermined region 7 in the modification. In an example of (1) in FIG. 19, an image region 5 contains 16 observation regions 4 arranged in a 4×4 grid and each region has a corresponding image. In this example, one predetermined region 7 is set for four observation regions 4. Vertical and horizontal sizes of the predetermined region 7 are larger than vertical and horizontal sizes of the observation region 4. Accordingly, a distribution using the four predetermined regions 7 arranged in a 2×2 grid is obtained.

In an example of (2) in FIG. 19, nine circular predetermined regions 7 are set for the 16 observation regions 4 arranged in a 4×4 grid in the image region 5. The circular predetermined regions 7 are provided at a center position of the image region 5, four positions shifted up, down, left, and right from the center position in an x-y direction, and four positions shifted to an upper left, upper right, lower left, and lower right with respect to the center position. Adjacent predetermined regions 7 partially overlap each other.

The user U1 may manually correct and adjust a component part after the correction portion is presented as correction necessary, but the invention is not limited thereto. When the charged particle beam device 2 has a function of automatically adjusting the component parts, information such as a correction portion may be transmitted from the computer 3 to the controller 200, and the controller 200 may use an automatic adjustment function to automatically adjust the component parts based on the information. The user U1 checks execution and result of the automatic adjustment on the GUI screen. As an example of the automatic adjustment function, in a case of adjusting the objective lens 108, a position and the like of the objective lens 108 can be adjusted by controlling a drive circuit connected to the objective lens 108.

### Embodiment 2

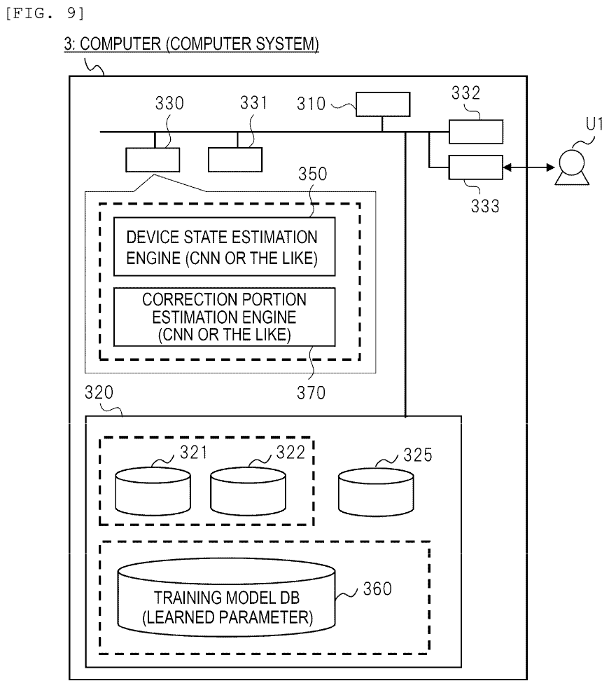

Embodiment 2 will be described with reference to FIG. 9 and subsequent figures. The basic configuration of Embodiment 2 and the like is the same as or common to that of Embodiment 1. The following will mainly describe the components of Embodiment 2 and the like that are different from Embodiment 1.

In the computer or the like according to Embodiment 2, a machine learning model is used to estimate a device state of the charged particle beam device 2 instead of the device state DB 323 described above. A specific example will be described below.

### Computer

FIG. 9 illustrates a functional block configuration of the computer 3 in the observation system 1 according to Embodiment 2. FIG. 9 is different from FIG. 1 in that the device state DB 323 and the device correction DB 324 are not provided in the storage 320 and a training model DB 360 is provided instead. The training model DB 360 is a DB in which learned parameters and the like constituting a training model of machine learning are stored. A specific example of the training model is a convolutional neural network (CNN). A device state estimation engine 350 is included as a function or a processing unit implemented by the processor 330 based on processing of the device management program 325. The device state estimation engine 350 is a part that performs processing of training of the training model of the training model DB 360 and evaluation and estimation of the device state using the training model. In other words, the device state estimation engine 350 is a device state estimation unit. The device management program 325 in Embodiment 2 has an implementation corresponding to the function in Embodiment 2.

The implementation of the device state estimation engine 350 is not limited to the configuration in FIG. 9. For example, as a configuration example of the observation system 1 in Embodiment 2, the device state estimation engine 350 and the training model DB 360 may be implemented in an external computer system separately from the computer 3. For example, an operator different from operators of the charged particle beam device 2 and the computer 3 provides a machine learning service on cloud computing. The computer 3 may cooperate with a server or the like provided by the operator through communication to use the device state estimation engine 350 or the like.

In Embodiment 2, the device state DB 323 in FIG. 7A in Embodiment 1 is replaced with the device state estimation engine 350. Further, in a modification of Embodiment 2, the device state DB 323 and the device correction DB 324 in FIG. 7A in Embodiment 1 are replaced with a correction portion estimation engine 370.

### State Estimation in Training Type

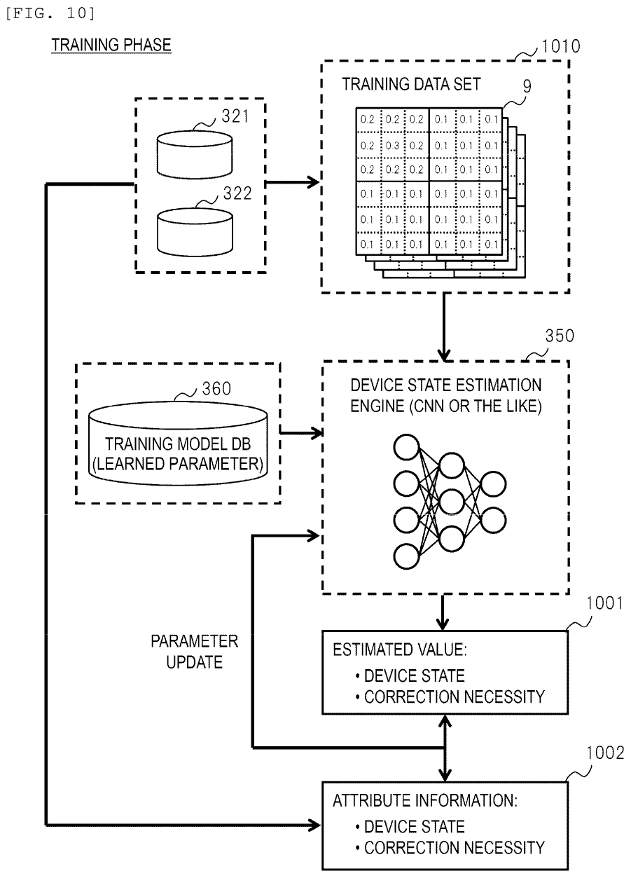

FIG. 10 is a diagram of training of the device state estimation engine 350 in a training phase. The computer 3 extracts at least one or more distributions 9 (the distribution for the temporal variations in the image quality evaluation values in the predetermined region described above) stored in the reference data DB 321 or the evaluation data DB 322, and creates a training data set 1010. The training data set 1010 is training data.

The device state estimation engine 350 executes processing based on internal parameters of the training model using each distribution of the training data set 1010 as an input, and outputs an estimated value 1001 as a processing result. The estimated value 1001, which is an output, has a probability that the distribution 9 corresponds to each of the label values indicating the device state, that is, a probability value of the device state, and a probability value of the correction necessity.

The device state estimation engine 350 (a training model corresponding thereto) learns a correlation between the distribution 9, the device state, and the correction necessity. Therefore, the device state estimation engine 350 refers to attribute information 1002 associated with each distribution 9 of the training data set 1010 from the reference data DB 321 or the evaluation data DB 322. The attribute information 1002 includes a label value indicating a device state and correction necessity. The device state estimation engine 350 updates the internal parameters of the training model so as to reduce an error between the attribute information 1002 and the estimated value 2001. The updated internal parameters are stored in the training model DB 360 as learned parameters. The above-described processing is executed in the training phase of the training model.

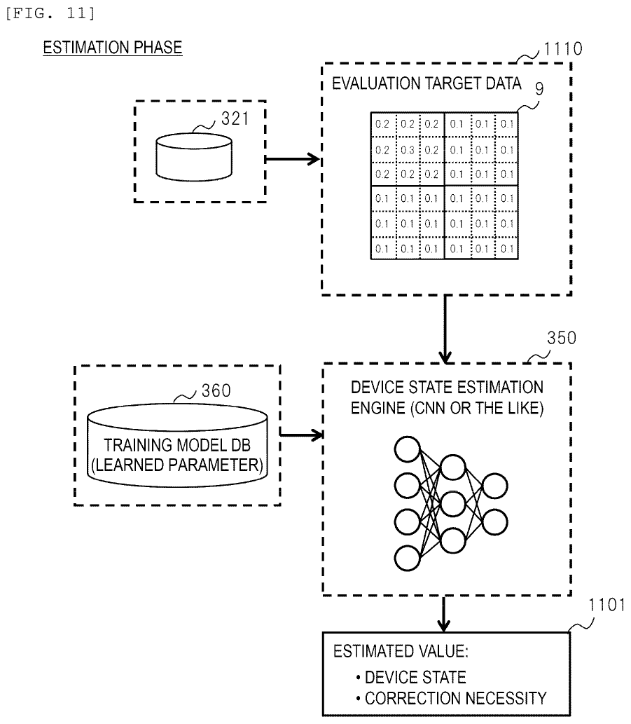

FIG. 11 is a diagram of the estimation phase. For evaluation target data 1110 including the evaluation target image referred to from the evaluation data DB 322, the computer 3 estimates the device state and the correction necessity using the device state estimation engine 350 based on the distribution 9 for the temporal variations in the image quality evaluation values in the predetermined region. The device state estimation engine 350 reads out and applies the corresponding internal parameters from the training model DB 360 so that the image quality evaluation function 430 used for calculating the distribution 9 is the same at the time of training and at the time of device state estimation. The device state estimation engine 350 executes processing based on the internal parameters using the distribution 9 of the evaluation target data 1110 in the evaluation data DB 322 as an input, and outputs the device state and the correction necessity at the generation time of the evaluation target data 1110 as an estimated value 1101 of the processing result.

In the modification, the estimation of the correction portion is further achieved by machine learning. For this purpose, the correction portion estimation engine 370 is used.

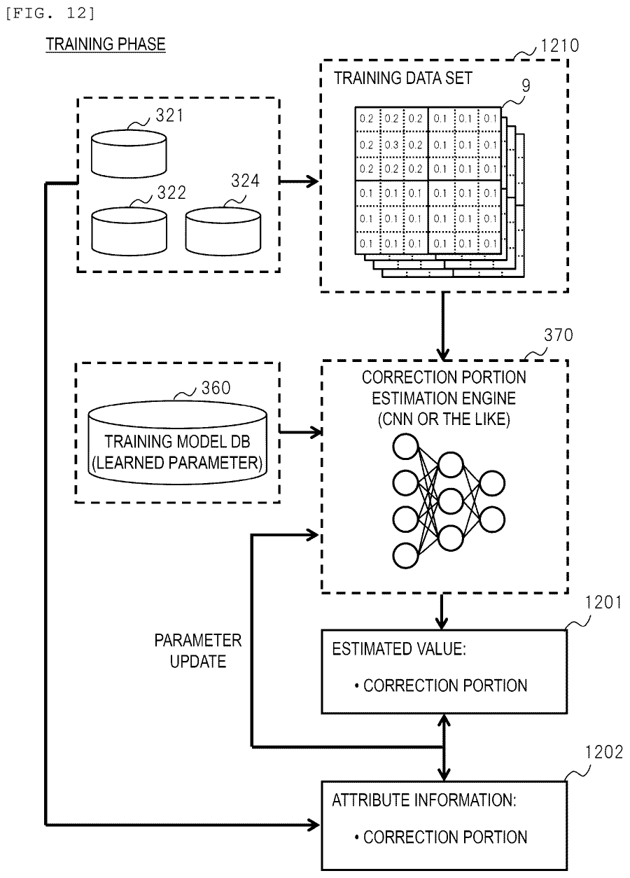

FIG. 12 is a diagram of training of the correction portion estimation engine 370 that estimates a correction portion based on the distribution 9 for the temporal variations in the image quality evaluation values in the predetermined region in the modification. The computer 3 extracts one or more distributions 9 stored in the reference data DB 321 or the evaluation data DB 322, and creates a training data set 1210. The correction portion estimation engine 370 executes processing based on the internal parameters of the training model using each distribution 9 of the training data set 1210 as an input, and outputs an estimated value 1201 as a processing result. The estimated value 1201, which is an output, has a probability value of a correction portion of the charged particle beam device 2 corresponding to the distribution 9. When there are a plurality of correction portions, each correction portion has a probability value. The correction portion estimation engine 370 (a training model corresponding thereto) learns a correlation between the distribution 9 and the correction portion. Therefore, the correction portion estimation engine 370 refers to attribute information 1202 from the reference data DB 321, the evaluation target data DB 322, and the device correction DB 324. The attribute information 1202 includes the correction portion. The correction portion estimation engine 370 updates the internal parameters of the training model so as to reduce an error between the attribute information 1202 and the estimated value 1201. The updated internal parameters are stored in the training model DB 360 as learned parameters. The above-described processing is executed in the training phase of the training model.

Although not illustrated in FIG. 9, the device correction DB 324 in FIG. 12 is used at the time of training and is not used at the time of estimation, and the correction portion estimation engine 370 performs estimation at the time of estimation.

FIG. 13 is a diagram of an estimation phase in the modification. In particular, FIG. 13 illustrates a case where the correction portion is estimated using the correction portion estimation engine 370 in combination with the estimation by the device state estimation engine 350 in FIG. 11, but the correction portion estimation engine 370 may be used alone.

### Effects, etc. of Embodiment 2

As described above, according to Embodiment 2, the state of the charged particle beam device 2 can be suitably managed. In particular, in Embodiment 2, it is possible to improve accuracy of estimation of a correspondence between the distribution 9 of the temporal variations in the image quality evaluation values of the image and the device state or the like by using the machine learning.

### Embodiment 3

Embodiment 3 will be described. In Embodiment 3, a device state of the charged particle beam device 2 is estimated by fitting. In Embodiment 3, an example in which fitting of a multivariate distribution model is used instead of the above-described device state DB 323 for estimating the device state of the charged particle beam device 2 will be described.

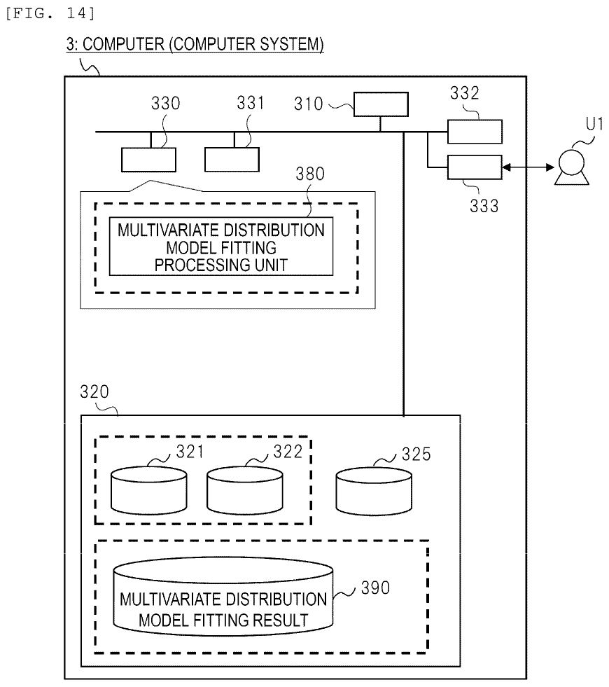

FIG. 14 illustrates a configuration example of the computer 3 in Embodiment 3. In Embodiment 3, the device state DB 323 in FIG. 7A in Embodiment 1 is replaced with a multivariate distribution model which is a mixed distribution model. The computer 3 includes a multivariate distribution model fitting processing unit 380 as a processing unit implemented by processing of the device management program 325 by the processor 330. The storage 320 stores a multivariate distribution model fitting result 390 and the like.

### Estimation of Device State by Multivariate Distribution Model

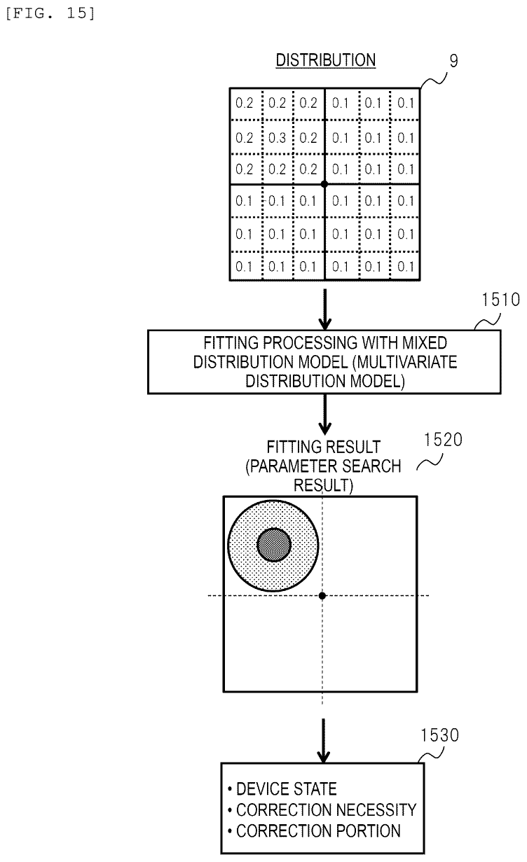

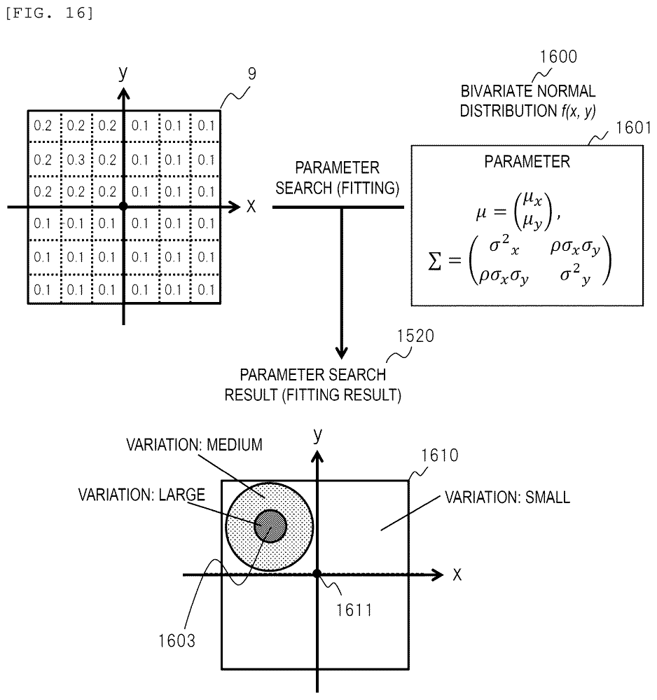

FIG. 15 is a diagram of the estimation of the device state by the multivariate distribution model. The computer 3 executes fitting processing 1510 (FIG. 16 described later) with the multivariate distribution model, which is the mixed distribution model, based on the distribution 9 for the temporal variations in the image quality evaluation values of the evaluation target data in the predetermined region, by the multivariate distribution model fitting processing unit 380, obtains a parameter search result as a fitting result 1520, and stores the parameter search result in the memory (multivariate distribution model fitting result 390 in FIG. 14). The computer 3 outputs the fitting result 1520 to the user U1. The computer 3 outputs, to the user U1, information on at least one of the device state, the correction necessity, and the correction portion based on the fitting result 1520.

### Fitting by Multivariate Distribution Model

FIG. 16 is a diagram of fitting by a multivariate distribution model. The computer 3 sets two orthogonal axes for the distribution 9. Here, as the two axes, the above-described x direction (=x-axis) and y direction (=y-axis) are similarly used. In the illustrated example, the x-axis and the y-axis are taken with a center point as an origin for a region of the distribution 9.

The computer 3 regards the temporal variations in the image quality evaluation values in each predetermined region 7 in the distribution 9 as a probability density, and approximates the probability density by a bivariate normal distribution 1600. In other words, the computer 3 fits the distribution 9 to the bivariate normal distribution 1600. The bivariate normal distribution 1600 is an example of the multivariate distribution model. The bivariate normal distribution 1600 can be expressed by two parameters 1601, a mean matrix u and a variance-covariance matrix 2. The computer 3 searches for the parameter 1601 that best fits the distribution 510 by a re-steep descent method or the like.

In the fitting result 1520 as the parameter search result, the mean matrix μ of the parameters indicates center coordinates of the distribution 9, and the variance-covariance matrix E indicates a spread manner of the distribution 9. From the searched parameters, the computer 3 can grasp a change center 1603 and the spread manner of the distribution 9 for the temporal variations in the image quality evaluation values in the predetermined region. In the illustrated example, the change center 1603 corresponds to a region where a value in the distribution 9 is 0.3. A portion corresponding to the change center 1603 has a relatively large variation, a ring-shaped portion around the portion has a relatively medium variation, and the other portions have a relatively small variation. A center of the x-y plane in the image region 1610 corresponding to the distribution 9 is indicated by a point 1611. The change center 1603 is located on an upper left of the center point 1611.

In the charged particle beam device 2, there are a plurality of adjustment portions that affect one image quality evaluation value, in other words, a plurality of correction candidate portions and corresponding component parts, which are closely related to each other. Therefore, in the related art, it is difficult to select an adjustment portion when the device state of the charged particle beam device 2 changes. In contrast, in Embodiment 3, the change center and the spread manner of the image quality evaluation value can be specified as in the parameter search result 1520. Accordingly, the adjustment portion for correcting the image quality evaluation value in which the change has occurred can be narrowed down as the correction portion. In other words, it is possible to easily narrow down suitable correction portions by giving priorities. It is possible to select a suitable correction portion in correspondence with a portion where the temporal variation in the image quality evaluation value is large and the spread manner and present the selected correction portion to the user U1.

For example, when the temporal variation in the blur amount, which is one of the image quality evaluation values, is larger near a periphery of the image region 1610, in other words, when there is a change center at a position away from the center toward the periphery, it can be estimated and determined that a change has occurred in a tendency of a field curvature. The field curvature is a difference in image formation distance between the charged particle beam 103 passing on-axis and off-axis of the objective lens 108 in FIG. 1. Therefore, one of the preferential correction portions can be narrowed down to the objective lens 108 based on the estimation and determination.

Examples of the spread manner include uniform, radial, and local forms. The example in FIG. 16 illustrates a radial spread manner in a concentric circle from the change center 1603. The correction portion can be determined based on information on the change center and the spread manner in the fitting result 1520. For example, a mode of the change center and the spread manner has a correspondence relationship with the component parts of the charged particle beam device 2, and the correction portion can be determined based on the correspondence relationship.

In Embodiment 3, after the parameter search result 1520 is obtained, as in Embodiment 1, the device state, the correction necessity, the correction portion, and the like may be estimated and output as subsequent processing. In Embodiment 3, for the determination of the device state, the correction necessity, and the correction portion, for example, the information on the distribution 731 in the device state DB 313 in FIG. 7B may be replaced with the parameter search result 1520 (for example, a mode of the change center and the spread manner) by the multivariate distribution model.

In Embodiment 3, the parameter search result 1520 based on the distribution 9, in other words, the distribution of temporal variations in image quality in the two-dimensional space is expressed as a graph, a map, or the like that is easy to visually understand. The computer 3 displays such a parameter search result 1520 on a GUI screen. The user U1 can see the parameter search result 1520 on the GUI screen and easily recognize the change center and the spread manner of the temporal variations in the image quality. Accordingly, the user U1 can suitably correct and adjust the objective lens 108 and the like.

### Effects, etc. of Embodiment 3

As described above, according to Embodiment 3, the state of the charged particle beam device 2 can be suitably managed. In particular, by using the multivariate distribution model, the change center and the spread manner in the distribution of the temporal variations in the image quality evaluation values can be suitably grasped with high accuracy, a suitable correction portion can be selected, and correction work by the user U1 can be made efficient.

### Embodiment 4

Embodiment 4 will be described. Embodiment 4 is a modification of a method of calculating the distribution 9 for the temporal variations in the image quality evaluation values in the predetermined region in FIG. 6 in Embodiment 1. In Embodiment 4, it is possible to cope with a case where observation regions of the evaluation target data and the reference data are different. In Embodiment 4, an evaluation method will be described in which when the computer 3 calculates the distribution 9, shapes of pattern structures in images of the evaluation target data and the reference data are different, in other words, there is a deviation.

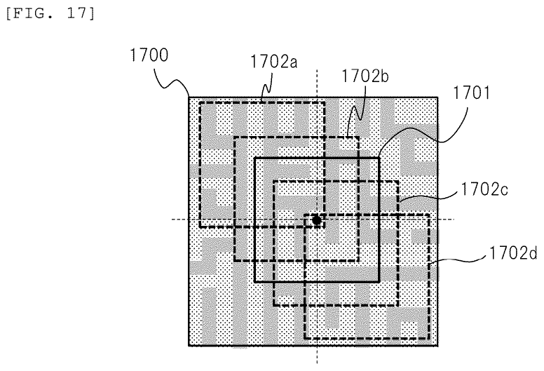

FIG. 17 illustrates an example in which the observation regions of the evaluation target image and the reference image are different. A region 1700 is an example of the same region on the surface of the sample 109. An evaluation target image 1701 is an image in a certain imaging position and imaging field for the region 1700. Reference images 1702a, 1702b, 1702c, and 1702d are images in the respective imaging positions and imaging fields. Since these images have slightly different imaging positions and imaging fields, regions including shapes of captured pattern structures are different. The region of the evaluation target image 1701 includes partial regions of the reference images 1702a, 1702b, 1702c, and 1702d.

### Method of Calculating Distribution When Observation Regions Are Different

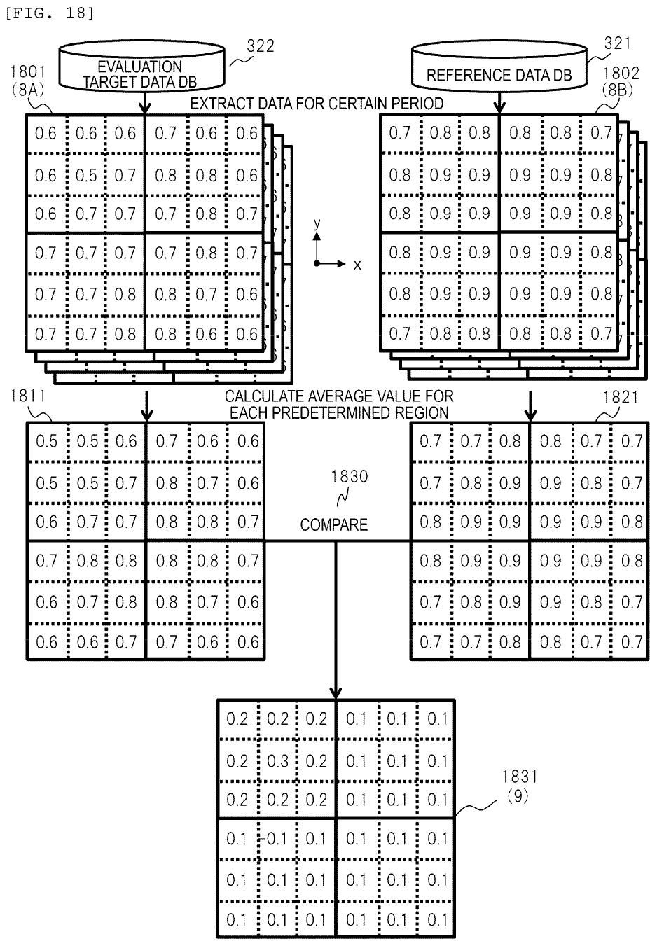

FIG. 18 is a diagram of the method of calculating the distribution 9 for the temporal variations in the image quality evaluation values in the predetermined region when the observation position and region of the sample 109 are different between the evaluation target data and the reference data. The computer 3 extracts, from the evaluation target data DB 322, a plurality of pieces of evaluation target data 1801 (the distribution 8A described above) within a certain evaluation period including a time at which the device state is estimated, and calculates, based on the plurality of pieces of evaluation target data 1801, an average value of image quality evaluation values for each predetermined region 7, in other words, for each predetermined region 7 at a corresponding position in x-y. The calculation result is an evaluation target average value distribution 1811.

The computer 3 extracts a plurality of pieces of reference data 1802 (the distribution 8B described above) including different observation regions from the reference data DB 321, and calculates an average value of image quality evaluation values for each predetermined region 7 based on the plurality of pieces of reference data 1802. The calculation result is a reference average value distribution 1821.

The computer 3 executes processing 1830 of comparing the average values for each predetermined region 7 between the evaluation target average value distribution 1811 calculated based on the plurality of evaluation target data 1801 and the reference average value distribution 1821 calculated based on the plurality of reference data 1802 and calculating a difference therebetween. Accordingly, the computer 3 obtains the distribution 9 for the temporal variations in the image quality evaluation values in the predetermined region as an average value difference distribution 1831 which is the calculation result.

Since the image quality evaluation value is affected by a pattern structure shape in the image to be evaluated, when the image quality evaluation values are compared, it is basically desirable that the images include the same pattern structure shape. Therefore, in Embodiment 1, the evaluation target image and the reference image having the same observation region are compared and evaluated. However, even when the evaluation target image and the reference image include different pattern structure shapes, in other words, even when there is a deviation in the observation region, it is possible to cope with the deviation by the processing using statistics as described above. That is, by using the average value of the image quality evaluation values based on a plurality of images in a certain period including various pattern structure shapes, it is possible to evaluate the image quality in consideration of an influence of a difference in pattern structure shapes between the evaluation target data and the reference data.

In a case of Embodiment 3, it is not necessary to perform imaging and management so that the imaging position and the imaging field are always the same in imaging and management of the reference image and the evaluation target image. Accordingly, even when there is no reference image of the reference data having the same observation position and region on the sample 109 as the evaluation target image of the evaluation target data, it is possible to appropriately estimate and manage the image quality evaluation and the device state.

Embodiments of the present disclosure have been specifically described above, but are not limited to the above-described embodiments, and various modifications can be made without departing from the scope of the invention. In each embodiment, components can be added, deleted, replaced, or the like except for essential components. Unless otherwise specified, each component may be single or plural. The embodiments and the modifications can be combined. Some or all of the configurations, functions, processing units, and the like described above may be implemented by hardware, for example by designing an integrated circuit, or may be implemented by software by a processor interpreting and executing a program. Data and information such as a program, a table, and a file for implementing the function can be stored in a recording device such as a memory, a hard disk, or SSD, or in a recording medium such as an IC card, an SD card, or a DVD.

For example, the controller 200 may perform all or a part of processing of the computer 3.

### Appendix

The following configuration is also possible as the present embodiment.

In the computer according to the embodiment, the processor acquires a plurality of evaluation target images in a certain period in the evaluation target data, calculates statistical values of image quality evaluation values for each predetermined region from the plurality of evaluation target images, acquires a plurality of reference images in the certain period in the reference data, calculates statistical values of the image quality evaluation values for each predetermined region from the plurality of reference images, compares a distribution of the statistical values of the image quality evaluation values of the reference data with a distribution of the statistical values of the image quality evaluation values of the evaluation target data, and calculates a distribution of temporal variations in the image quality evaluation values.

In the computer according to the embodiment, the processor acquires an image group including at least a first image in which the first observation region is captured and a second image in which a second observation region is captured by moving the imaging field coordinate by deflecting the charged particle beam by the charged particle beam device, and calculates a first distribution of the image quality evaluation values for each predetermined region with respect to an image region of the image group.

In the computer according to the embodiment, the processor acquires an image group including at least the first image in which the first observation region is captured and the second image in which the second observation region is captured by the charged particle beam device simultaneously irradiating the sample with a plurality of charged particle beams while scanning the sample, and calculates the first distribution of the image quality evaluation values for each predetermined region with respect to the image region of the image group.

### REFERENCE SIGNS LIST

1: observation system
2: charged particle beam device
3: computer
4: observation region
5: observation region
6: image
7: predetermined region
8A, 8B: distribution
9: distribution (distribution for temporal variations in image quality evaluation values in predetermined region)
100: main body
200: controller
330: processor
331: memory
320: storage
321: reference data DB
322: evaluation target data DB
323: device state DB
324: device correction DB
601: evaluation target data
602: reference data

1. A computer comprising:
a processor; and
a storage resource that stores a program, wherein
the storage resource stores reference data obtained by a charged particle beam device or simulation, with a sample as the target, the reference data including an imaging field coordinate of the charged particle beam device, a generation time of a reference image in which an observation region corresponding to the imaging field coordinate is captured, and a distribution of reference image quality evaluation values obtained from the reference image by an image quality evaluation function for each predetermined region, and
the processor that executes processing according to the program
(1) acquires an evaluation target image, which is obtained by the charged particle beam device, with the sample as the target and in which the observation region corresponding to the imaging field coordinate is captured, in an evaluation period including an evaluation time,
(2) stores, in the storage resource, evaluation target data including the imaging field coordinate, the evaluation time, and a first distribution of image quality evaluation values obtained from the evaluation target image by the image quality evaluation function for each predetermined region, and
(3) compares the reference data with the evaluation target data to calculate a distribution of temporal variations in the image quality evaluation values by the image quality evaluation function.

2. The computer according to claim 1, wherein
the processor estimates a state of the charged particle beam device at the evaluation time based on a correlation between the distribution of the temporal variations in the image quality evaluation values and the state of the charged particle beam device.

3. The computer according to claim 2, wherein
the processor determines correction necessity of a component part of the charged particle beam device based on the distribution of the temporal variations in the image quality evaluation values or an estimation result of the state of the charged particle beam device, and outputs the correction necessity as a determination result.

4. The computer according to claim 2, wherein
the processor determines a correction portion of a component part of the charged particle beam device based on the distribution of the temporal variations in the image quality evaluation values or an estimation result of the state of the charged particle beam device, and outputs the correction portion as a determination result.

5. The computer according to claim 2, wherein
the storage resource stores a database in which the correlation between the distribution of the temporal variations in the image quality evaluation values and the state of the charged particle beam device is stored, and
the processor inputs the distribution of the temporal variations in the image quality evaluation values to the database and obtains an estimated value of the state of the charged particle beam device as an output.

6. The computer according to claim 2, wherein
the processor inputs the distribution of the temporal variations in the image quality evaluation values to a model in which the correlation between the distribution of the temporal variations in the image quality evaluation values and the state of the charged particle beam device has been learned, and obtains an estimated value of the state of the charged particle beam device as an output.

7. The computer according to claim 2, wherein
the processor fits a multivariate distribution model to the distribution of the temporal variations in the image quality evaluation values, and obtains an estimated value of the state of the charged particle beam device based on a parameter of the multivariate distribution model.

8. The computer according to claim 4, wherein
the storage resource stores a database in which a correlation between the state of the charged particle beam device and the correction portion of the component part of the charged particle beam device is stored, and
the processor inputs an estimation result of the state of the charged particle beam device to the database and obtains the correction portion as an output.

9. The computer according to claim 4, wherein
the processor inputs the distribution of the temporal variations in the image quality evaluation values to a model in which a correlation between the distribution of the temporal variations in the image quality evaluation values and the correction portion of the component part of the charged particle beam device has been learned, and obtains an estimated value of the correction portion of the component part of the charged particle beam device as an output.

10. The computer according to claim 1, wherein
the distribution of the temporal variations in the image quality evaluation values is displayed on a screen provided to a user.

11. The computer according to claim 1, wherein
the predetermined region is a region obtained by dividing an image region of one or more evaluation target images into regions with a shape, a size, and a number according to an image quality evaluation value of a calculation target, and
the predetermined region is set or predetermined region setting information set in advance is selected and applied based on an operation of a user on a screen provided to the user.

12. The computer according to claim 1, wherein
the image quality evaluation value obtained by the image quality evaluation function is at least one of luminance, contrast, a blur amount, and a distortion amount.

13. The computer according to claim 1, wherein
the processor
calculates a blur amount for each direction in an image as the image quality evaluation value, and
outputs an objective lens or an astigmatism corrector as a correction portion, which is a component part of the charged particle beam device, based on a distribution of the blur amount for each direction.

14. A program that is the program according to claim 1.

15. A method executed by a computer including a processor and a storage resource that stores a program,
the storage resource storing reference data obtained by a charged particle beam device or simulation, with a sample as the target, the reference data including an imaging field coordinate of the charged particle beam device, a generation time o a reference image in which an observation region corresponding to the imaging field coordinate is captured, and a distribution of reference image quality evaluation values obtained from the reference image by an image quality evaluation function for each predetermined region,
the method comprising:
by the processor that executes processing according to the program,
(1) a step of acquiring an evaluation target image, which is obtained by the charged particle beam device, with the sample as the target and in which the observation region corresponding to the imaging field coordinate is captured, in an evaluation period including an evaluation time;
(2) a step of storing, in the storage resource, evaluation target data including the imaging field coordinate of the charged particle beam device, the evaluation time, and a first distribution of image quality evaluation values obtained from the evaluation target image by the image quality evaluation function for each predetermined region; and
(3) a step of comparing the reference data with the evaluation target data to calculate a distribution of temporal variations in the image quality evaluation values by the image quality evaluation function.
